(19) United States
(12) Patent Application Publication
(10) Pub. No.: US 2025/0299722 A1
(43) Pub. Date: Sep. 25, 2025

(54) APPARATUSES SYSTEMS AND METHODS FOR MEMORY WITH ACCESS BASED REFRESH CONTROL

(71) Applicant: MICRON TECHNOLOGY, INC., BOISE, ID (US)

(72) Inventors: Sujeet Ayyapureddi, Boise, ID (US); Gary Howe, Allen, TX (US)

(73) Assignee: MICRON TECHNOLOGY, INC., Boise, ID (US)

(21) Appl. No.: 19/061,872

(22) Filed: Feb. 24, 2025

Related U.S. Application Data
(60) Provisional application No. 63/567,741, filed on Mar. 20, 2024.

(51) Int. Cl. G11C 11/406; G06F 3/06

(52) U.S. Cl. CPC G11C 11/406; G06F 3/0625; G06F 3/0653; G06F 3/0673

(57) ABSTRACT

A memory device receives a command, address, or combination thereof as part of an access operation which indicates an opportunity to perform a refresh background operation. The memory device may determine whether or not to perform the background refresh operation. If a background refresh operation is performed, the memory accesses a word line in a first section of a memory bank and refreshes a word line in a different section of the memory bank. In some embodiments, an opportunity background refresh operation may be signaled by an access command with an extended timing window.

### CROSS-REFERENCE TO RELATED APPLICATIONS

This application claims the filing benefit of U.S. Provisional Application No. 63/567,741, filed Mar. 20, 2024. This application is incorporated by reference herein in its entirety and for all purposes.

### BACKGROUND

This disclosure relates generally to semiconductor devices, and more specifically to semiconductor memory devices. In particular, the disclosure relates to volatile memory, such as dynamic random access memory (DRAM). Information is stored in the memory on memory cells as a physical signal such as a charge on a capacitive element. During an access operation, an access command may be received along with address information which specifies which memory cells should be accessed.

Information may decay over time in the memory cells. For example, the memory cells may discharge over time. In order to preserve the integrity of the stored information, the memory cells may be refreshed, for example to restore an initial charge level associated with the stored information. The memory receives a refresh command which instructs it to perform one or more refresh operations. However, the memory device may generally be unavailable for access operations while performing refresh operations. It may be desirable to find ways to reduce the amount of time the memory is unavailable for access operations while still making sure that refresh operations are occurring.

### BRIEF DESCRIPTION OF THE DRAWINGS

FIG. 1 is a block diagram of a semiconductor device according to some embodiments of the disclosure.

FIG. 2 is a block diagram of a memory system according to some embodiments of the present disclosure.

FIG. 3 is a block diagram of a memory device according to some embodiments of the present disclosure.

FIG. 4 is a flow chart of a method of performing background refresh operations according to some embodiments of the present disclosure.

FIG. 5 is a flow chart of a method of determining whether or not to perform a background refresh operation according to some embodiments of the present disclosure.

FIG. 6 is a table of an example of how an extended activation command may be transmitted to the memory according to some embodiments of the present disclosure.

FIG. 7 is a timing diagram of a background refresh operation according to some embodiments of the present disclosure.

FIG. 8 is a flow chart of a method of sending access commands to a memory according to some embodiments of the present disclosure.

FIG. 9 is a flow chart of a method of performing background refresh operations according to some embodiments of the present disclosure.

FIG. 10 is a timing diagram of background refresh operations according to some embodiments of the present disclosure.

FIG. 11 is a flow chart of a method of providing access commands with different timing based on an address according to some embodiments of the present disclosure.

FIG. 12 is a flow chart of a method of maintaining a refresh deficit count and determining a count value to write to a mode register according to some embodiments of the present disclosure.

FIG. 13 is a timing diagram of protocols to coordinate mode register access between a memory device and a controller according to some embodiments of the present disclosure.

FIG. 14 is a flow chart of a method coordinating mode register access between a memory device and a controller according to some embodiments of the present disclosure.

FIG. 15 is a flow chart of a method of aggregating refresh deficit counts from a plurality of banks to determine a refresh scheme according to some embodiments of the present disclosure.

FIG. 16 shows a flow chart of a method of indicating the need for a targeted refresh operation according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present apparatuses, systems, methods, and combinations thereof, reference is made to the accompanying drawings. The drawings are shown by way of illustration of specific example embodiments of how the described apparatuses, systems, methods, or combinations thereof may be practiced. These embodiments are described in sufficient detail to enable those skilled in the art to practice presently disclosed apparatuses, systems, methods, and combinations thereof, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory device includes a memory array. The memory array includes a number of memory cells. The memory cells are at the intersection of bit lines and word lines. The bit lines and word lines may be considered as columns and rows respectively in a logical organization of the array. The memory array is also divided into multiple banks. Accordingly, a row address may specify one or more word lines, a column address may specify one or more bit lines, and a bank address may specify one or more banks.

During an access operation such as a read or write operation, the memory receives an access command along with a bank, row, and column address. The memory receives a row activation command and activates the word line specified by the row address in the bank specified by the bank address. While active, data may be read or written along the bit lines specified by the column address. The bit lines are coupled to sense amplifiers. The sense amplifiers sense a voltage on the bit line from the memory cells along the active word line and amplify it into a signal in a read operation or drive a voltage to the memory cell along the active word line in a write operation. Each bank is divided into sections. In some embodiments, a bank is divided into sections, with each section separated from its neighboring sections by a strip of sense amplifiers that are coupled to the bit lines extending into the neighboring sections. Accordingly, the row address may specify which section is being accessed. The sense amplifiers are shared by the neighboring sections, with the sense amplifiers used by one of the neighboring sections during an access operation.

During a refresh operation, the memory receives a refresh command that specifies one or more banks, such as a per-bank refresh command, same bank refresh command or all bank refresh command. Responsive to the command, the specified bank(s) perform one or more refresh operations on a row-by-row basis. However, while performing refresh operations, the memory device, or at least the specified banks, may be unavailable for access operations. It may thus be desirable to reduce the number of refresh commands which are sent, reduce the duration of a refresh operations, or combinations thereof. Reducing unnecessary refresh operations may reduce the memory's downtime, reduce its power consumption, or combinations thereof. However, it is still important to ensure that the memory is performing refresh operations at rate such that information is not lost.

The present disclosure is drawn to apparatuses, systems, and methods for access based refresh operations. In at least some example embodiments, the present disclosure relates to a memory device that receives an access operation which allows an opportunity for a refresh operation on memory cells other than the memory cells that are accessed for the access operation. For example, the memory determines if a refresh operation is needed and possible, and then performs a refresh operation on a word line in a different section than the section being accessed. The word lines may be active at overlapping periods of time. In this way, refreshes may occur while the memory is being accessed. Refresh operations performed during access operations in this manner may generally be referred to as background refresh operations. Refresh operations performed on their own, for example in response to a refresh command, may generally be referred to as stand-alone refresh operations. The use of background refresh operations may help decrease or even eliminate the number of stand-alone refresh operations. Since access operations occur during background operations, but not when a stand-alone refresh operation occurs, the reduction of stand-alone refresh operations may decrease a downtime of the memory. In addition, when stand-alone refresh operations are performed, they may have a reduced duration compared to conventional devices where only stand-alone refreshes are performed, since fewer refresh operations may be required to address the refresh deficit.

In at least some example embodiments, the memory may track how many refresh operations have been performed compared to how many refresh operations are expected to be performed, in order to generate a refresh deficit count. The refresh deficit count may be used to determine if a refresh operation should be performed or not. The memory may use the refresh deficit count to determine when to perform a refresh operation either for background refresh operations or for refresh operations performed responsive to a refresh command. In some embodiments, the deficit counts may be kept on a bank-by-bank basis, or on portions thereof. For example, if the deficit is zero, then the memory has already performed enough refreshes on that portion of the bank, and even if a refresh opportunity is possible, the memory may skip performing that refresh. In another example, if the deficit count indicates a refresh deficit for a bank, the memory will need to refresh memory of the bank. The use of logic on the memory to determine whether or not to perform refresh operations (either background, stand alone, or combinations thereof) may help to reduce power consumption, downtime requirements, or combinations thereof.

In some example embodiments, the present disclosure relates to a controller. The controller monitors a memory device to determine if refresh commands are required. For example, the controller may periodically read the refresh deficit counts from the memory. If at least one deficit count is above zero, indicating at least one bank has a refresh deficit, the controller sends a refresh command. The deficit counts may be associated with banks of the memory device, and the controller may determine what type of refresh command to send based on which banks indicate a deficit. For example, if only a single bank has a deficit, then a per-bank refresh command may be sent to that bank. The refresh command may cause the memory to perform a stand-alone refresh operation.

In some example embodiments, the present disclosure relates to a memory system with a controller and a memory. The memory generates refresh deficit counts based on a comparison of refresh operations performed to expected refresh operations performed. The controller sends access commands which allow for a background refresh operation in the specified bank and the memory uses the deficit count for that bank to determine whether or not to perform a background refresh in the bank. The controller also reads the deficit counts and determines whether or not to send refresh commands. When the memory receives a refresh command, a refresh control circuit of each bank specified by the refresh command may use its respective deficit count(s) to determine whether or not to perform a stand-alone refresh operation or not.

In an example implementation, the controller determines whether to send a first type of row activation command or a second type of row activation command as part of an access operation. The second type of activation command indicates an extended timing window compared to the first type of activation command. Responsive to the second type of activation command, the memory checks a deficit counter associated with the accessed bank. If the deficit counter is non-zero, then the memory may determine that a refresh on that bank is called for and check if the accessed row address allows for a refresh operation. Whether a refresh operation is allowed may be determined, in some embodiments, for example by comparing row address received as part of the access operation to a current value of a first refresh address counter and a second refresh address counter. The first and the second refresh address counters keep track of a current refresh address in a first portion and a second portion of the memory bank. Performing a background refresh on certain sections may be forbidden based on which row address is being accessed. The memory checks to determine if either or both of the current refresh address values is refreshable. If at least one is, then the memory may access the row indicated by the row address, and while that row is being accessed, refresh the row indicated by the selected refresh address. That refresh address counter is updated. The memory compares the two refresh address counters, which indicate how many refreshes have been performed, to each other, and a lower of the two refresh address counters is compared to a global refresh period counter that tracks an expected number of refresh operations at that point in time. The difference is used to generate the refresh deficit count. The controller may periodically check those refresh deficit counts to determine whether or not to send a refresh command. In at least some example embodiments, the memory may perform certain background refresh operations even when the first type of activation command is received, based on a comparison between a section select bit of the received row address and a section select bit of the previously received row address.

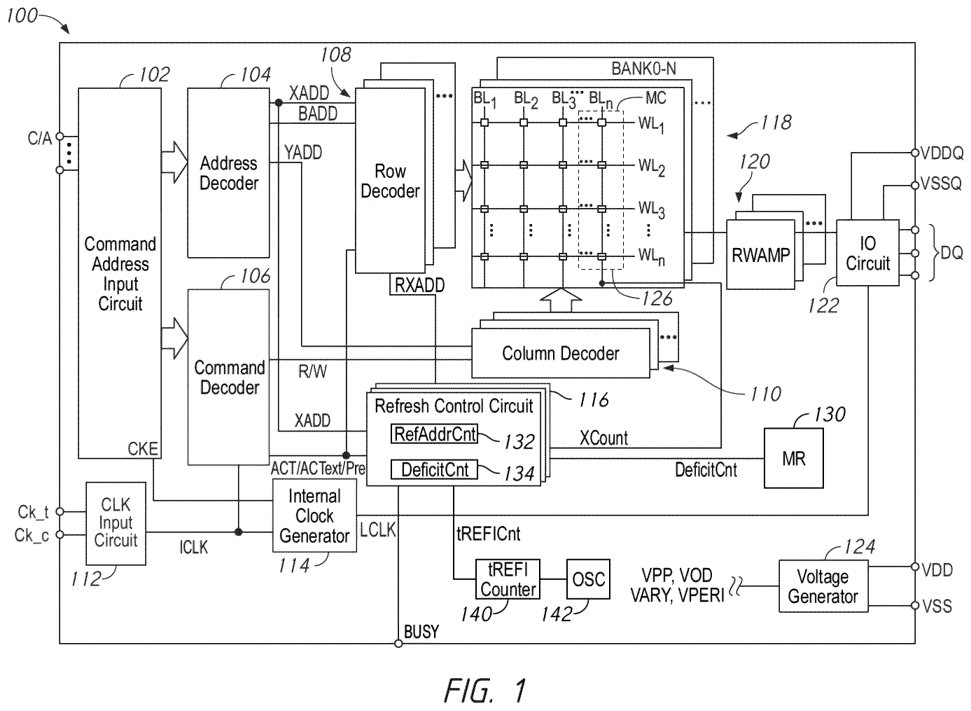

FIG. 1 is a block diagram of a semiconductor device according to some embodiments of the disclosure. The semiconductor device 100 may be a semiconductor memory device, such as a DRAM device integrated on a single semiconductor chip. In some embodiments, the semiconductor device 100 may represent one of a number of memory devices packaged together, such as on a module. In some embodiments, the semiconductor device 100 may represent a stand-alone memory device.

The semiconductor device 100 includes a memory array 118. The memory array 118 is organized into a plurality of memory banks. In the embodiment of FIG. 1, the memory array 118 is shown as including N+1 memory banks labeled BANK0 to BANKN. For example, a memory array 118 may include 4, 8, 16, or any other number of memory banks. More or fewer banks may be included in the memory array 118 of other embodiments.

Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank.

The bit lines BL are coupled to a respective sense amplifier (SAMP). Read data from the bit line BL is amplified by the sense amplifier SAMP, and transferred to read/write amplifier (RWAMP) circuit 120 over local data lines (LIO), transfer gate (TG), and global data lines (GIO). Conversely, write data outputted from the RWAMP circuit 120 is transferred to the sense amplifier SAMP over the complementary main data lines GIO, the transfer gate TG, and the complementary local data lines LIO, and written in the memory cell MC coupled to the bit line BL.

The semiconductor device 100 may employ a plurality of external terminals, such as solder pads, that include command and address (C/A or CA) terminals coupled to a command and address bus to receive commands and addresses, clock terminals to receive clocks CK and/CK, data terminals DQ coupled to a data bus to provide data, and power supply terminals to receive power supply potentials VDD, VSS, VDDQ, and VSSQ. The external terminals may also generally be referred to as ‘pins’ such as C/A pins. In some embodiments, the external terminals may couple directly to a host or controller of the memory device 100. In some embodiments, the external terminals may couple to various buses/connectors of a module or other package. The terminals may also be referred to as pins. In some embodiments, each terminal may generally receive a first voltage which represents a logical high or a second voltage which represents a logical low. Other schemes, such as multi-level signaling (e.g., PAM4) may be used in other example embodiments.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data. The input/output circuit 122 may include a number of interface connections, each of which may be couplable to one of the DQ pads (e.g., the solder pads which may act as external connections to the device 100).

The C/A terminals may be supplied with memory addresses. The memory addresses supplied to the C/A terminals are transferred, via a command/address input circuit 102, to an address decoder 104. The address decoder 104 decodes the address into a bank address, row address, and column address. The bank address BADD selects the row decoder 108 and column decoder 110 and thus selects the bank. The address decoder 104 supplies a decoded row address XADD to the row decoder 108 selected by BADD and supplies a decoded column address YADD to the column decoder 110 selected by BADD. The decoded row address XADD may be used to determine which row is opened or activated, coupling the memory cells along the activated word line to the intersecting bit lines. The column decoder 110 provides a column select signal CS based on the column address YADD. The CS signal selects which bit lines are coupled to local input/output lines, allowing those bit lines to be accessed.

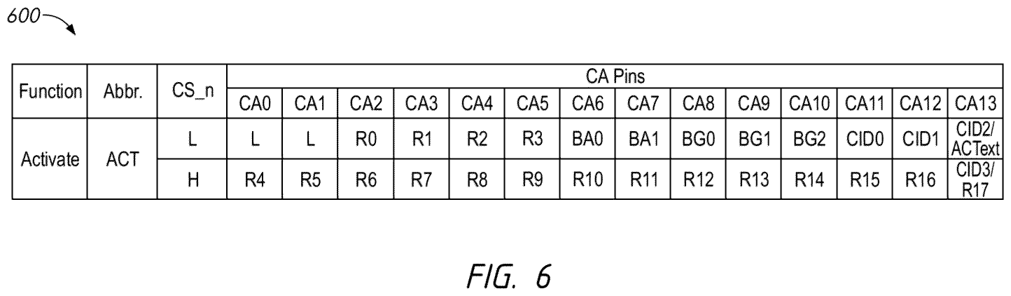

The C/A terminals may be supplied with commands. Examples of commands include timing commands for controlling the timing of various operations, access commands for accessing the memory, such as read commands for performing read operations and write commands for performing write operations, refresh commands such as all-bank refresh, same bank refresh, and per-bank refresh, as well as other commands and operations. The access commands may be associated with one or more row address XADD, column address YADD, and bank address BADD to indicate the memory cell(s) to be accessed. In some embodiments, the command and address may be transmitted together as a command packet along the C/A terminals. The input circuit 102 separates the command portion of the packet from the address portion and provides the command portion to the command decoder 106 and the address portion to the address decoder 104. An example access command includes an activation command packet ACT, which includes the activation command, row address, and bank address. An example activation command packet is described in more detail in FIG. 6.

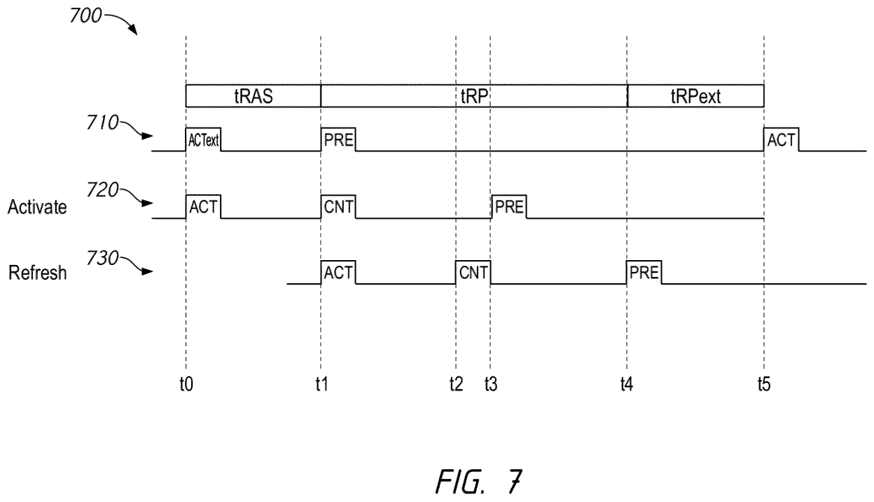

The commands may be provided as internal command signals to a command decoder 106 via the command/address input circuit 102. The command decoder 106 includes circuits to decode the internal command signals to generate various internal signals and commands for performing operations. For example, the command decoder 106 may provide signals to indicate if data is to be read, written, etc. Responsive to an activation command received at the C/A terminals, as part of an access operation the command decoder 106 provides an internal row activation command or internal row activation signal ACT and an internal pre-charge command or internal pre-charge signal Pre. The row decoder 108 activates a word line responsive to the internal activation signal ACT and deactivates (or pre-charges) the word line responsive to the internal pre-charge signal Pre. The timing between ACT and Pre, as well as how many rows are activated, may be changed based on the type of command as described in more detail herein. Examples of different timings are described in more detail in FIGS. 7-11.

In an example write operation, the device 100 writes data received at the DQ terminals to the memory cells specified by a received bank, row and column address. As part of the write operation, the command decoder 106 receives a write command and activation command and provides internal signals such as W and ACT/Pre. The write data is received by the IO circuit 122 and provided to the RWAMP circuit 120. The row decoder 108 selected by BADD activates the row selected by XADD responsive to the internal activation signal ACT. The column decoder 110 selected by BADD couples the bit lines selected by YADD to the LIO and GIO lines to the RWAMP circuit 120. The sense amplifiers drive the voltages on the coupled bit lines to write the write data to the memory cells at the intersection with the active word line.

In an example read operation, the device 100 reads data from the memory cells specified by a received bank, row, and column address and provides that read data to the DQ terminals. As part of the read operation, the command decoder 106 receives a read command and an activation command and provides internal signals such as a read signal R, and ACT/Pre. The row decoder 108 selected by BADD activates the row selected by XADD responsive to the internal row activation signal ACT. The column decoder 110 selected by BADD couples the bit lines selected by YADD to the LIO and GIO lines to the RWAMP circuit 120. The RWAMP circuit 120 provides the read data to the IO circuit 122 and the IO circuit 122 provides the read data to the DQ terminals.

The device 100 includes a mode register 130. The mode register includes a number of storage elements, such as latch circuits, organized in registers. The registers store information such as settings of the memory, information about the memory, or combinations thereof. A controller may perform a mode register read operation to retrieve information from a specified register or a mode register write operation to write information to a specified register. Some registers may be read only to prevent the controller from modifying them. Some registers may be updated based on conditions or operations of the memory. For example a refresh rate multiplier register may be set based on a measured temperature of the array 118.

The device 100 includes refresh control circuits 116 each associated with a bank of the memory array 118. Each refresh control circuit 116 may determines when to perform a refresh operation on the associated bank. The refresh control circuits 116 receive a command, address, or combinations thereof as part of an access operation that indicate a refresh opportunity, as described in more detail herein. For example, the command decoder 106 may receive an access command that indicates an extended timing window or a normal access command with a shorter timing window. If the access command includes the extended timing window, the command decoder provides an extended activation command ACText. Responsive to ACText, the refresh control circuit 116 may determine that there is a background refresh opportunity. In some embodiments, the memory device 100 may receive an extended activation command ACText as part of an activation command packet along the C/A terminals. In some embodiments, the extended activation may be signaled by a previous Pre charge command being an extended command Preext, and the command decoder 106 provides ACText a next time an activation command is received. The extended activation ACText may be an opportunity for a background refresh operation to be performed during that access operation.

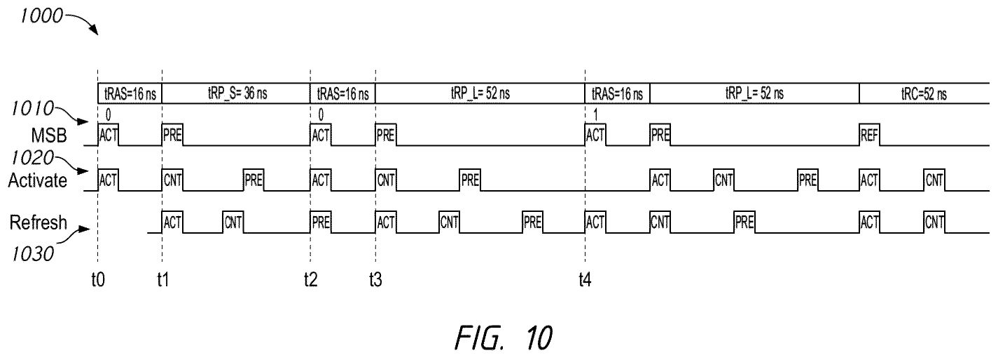

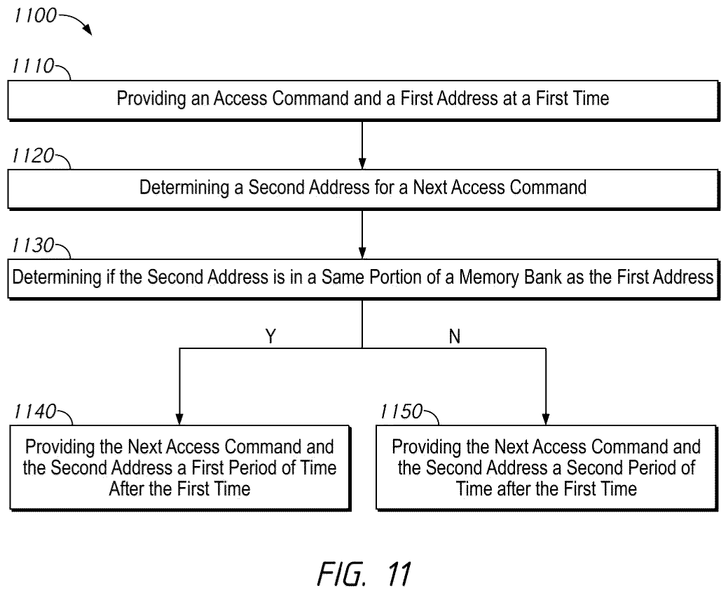

In some embodiments, the controller may give the memory 100 the opportunity to perform a background refresh operation without extending the timing window of an access operation. For example, if the controller accesses a same portion of the array 118 on two consecutive access operations, it may indicate a background refresh opportunity to the memory 100 even if the access command specifies a normal, non-extended, timing window. For example, the controller may indicate a background refresh opportunity is available by setting a bit in the row address which accompanies an ACT command. A background refresh may be performed without extending the timing window if the controller will issue the next ACT command to the same portion of the array. For example, if an ACT command at a first time includes a row address with a section select bit in a first state and a next ACT command includes a row address with the section select bit in the same state, then background refresh operation occurs in a different portion of the array (e.g., the portion specified by the other state of the section select bit), resulting in no conflict between background refresh completing and activation of the row corresponding to the second ACT command. This allows the controller to send access commands with a shortened timing window while still allowing background refresh operations. Example embodiments which use a section select bit are described in more detail in FIGS. 10-11.

When the refresh control circuit 116 determines that there is a refresh opportunity for that bank, either stand-alone or background, the refresh control circuit 116 determines whether or not to perform a refresh operation. For example, the refresh control circuit 116 may determine whether or not to perform a refresh operation based at least in part on if a refresh operation is called for, and if a refresh operation is possible. If the refresh control circuit determines to perform a background refresh operation, the refresh control circuit 116 performs a background refresh operation by generating a refresh address RXADD. The row decoder 108 refreshes a word line associated with RXADD while the word line associated with XADD is being accessed as part of the access operation. In some embodiments, the memory 100 can also receive a refresh command separate from an access command. Responsive to a refresh command, the refresh control circuit 116 determines whether or not to perform a refresh operation and generates RXADD. However if a refresh operation is performed responsive to a refresh command, it is a stand-alone refresh operation on the word line associated with RXADD, and no other different word line is accessed. In some embodiments, multiple word lines may be specified by the refresh address RXADD and the row decoder 108 may refresh all of the word lines associated with RXADD.

The refresh control circuit 116 includes one or more refresh address counter circuits 132, which are used to generate a refresh address RXADD. Each time a refresh operation is performed, the refresh address counter 132 is updated (e.g., incremented) to generate a new value. In this way, the refresh address RXADD counts through the word lines of the bank.

The memory device 100 includes a refresh period counter 140. The memory device 100 may need to perform a certain number of refresh operations in a refresh window. For example, the memory device 100 may need to perform J refresh operations in a refresh window of K ms. In some embodiments, the value of the number of refresh operations (J), the value of the length of the refresh window (K), or combinations thereof, may be set based on values in the mode register 130, such as a refresh setting, a temperature of the memory, or combinations thereof. The memory device 100 sets a refresh interval tREFI based on the average interval between refresh operations in order to perform J operations in K amount of time. For example, tREFI=K/J. The refresh period counter 140 updates a refresh period count tREFIcnt every tREFI amount of time. The refresh period counter 140 may be coupled to an oscillator circuit 142, to a clock signal, or combinations thereof to count time. The tREFI counter 140 may reset the count tREFIcnt to an initial value at power up/reset or when the count reaches J. In this way the refresh interval count may represent a number of refreshes which should have been performed so far in the current refresh window.

The refresh address counter 132 tracks a number of refresh operations which have been performed so far. The refresh address counter 132 tracks a refresh address count RefAddrCnt, which may be used to generate the refresh address RXADD. In some embodiments, the refresh address count RefAddrCnt may be used as the refresh address RXADD directly. In some embodiments, the refresh control circuit 116 may generate the refresh address RXADD based on the refresh address count RefAddrCnt. The refresh control circuit 116 compares the refresh address count RefAddrCnt to the refresh interval count tREFIcnt. Based on that comparison, the refresh control circuit 116 sets a refresh deficit count DeficitCnt 134. The refresh deficit count DeficitCnt 134 may be stored in storage elements of the memory 100 such as in register circuits or latch circuits. In some embodiments, if the refresh address count RefAddrCnt is equal to or greater than tREFIcnt, then the refresh deficit count DeficitCnt 134 is set to 0. If the refresh address count RefAddrCnt is less than tREFIcnt, then the refresh deficit count DeficitCnt 134 is set to the difference between tREFIcnt and RefAddrCnt.

The refresh control circuit 116 uses the refresh deficit count DeficitCnt 134, in part, to determine whether or not to perform a refresh operation. For example, if the deficit count DeficitCnt is 0, then a refresh operation may be skipped, even if the refresh control circuit receives a refresh opportunity. If the deficit count is non-zero, then a refresh operation may be performed when the refresh control circuit 116 is presented with a refresh opportunity. In this manner, each bank or each portion of a bank as described in more detail herein, may be able to determine whether or not to perform a refresh when given the opportunity to do so, either responsive to an access operation or responsive to a refresh command. In some embodiments, a refresh may be performed even if the deficit count is zero. For example, the memory device 100 may perform up to a threshold number of operations even when the deficit count is zero in order to get ahead of the expected number of refreshes.

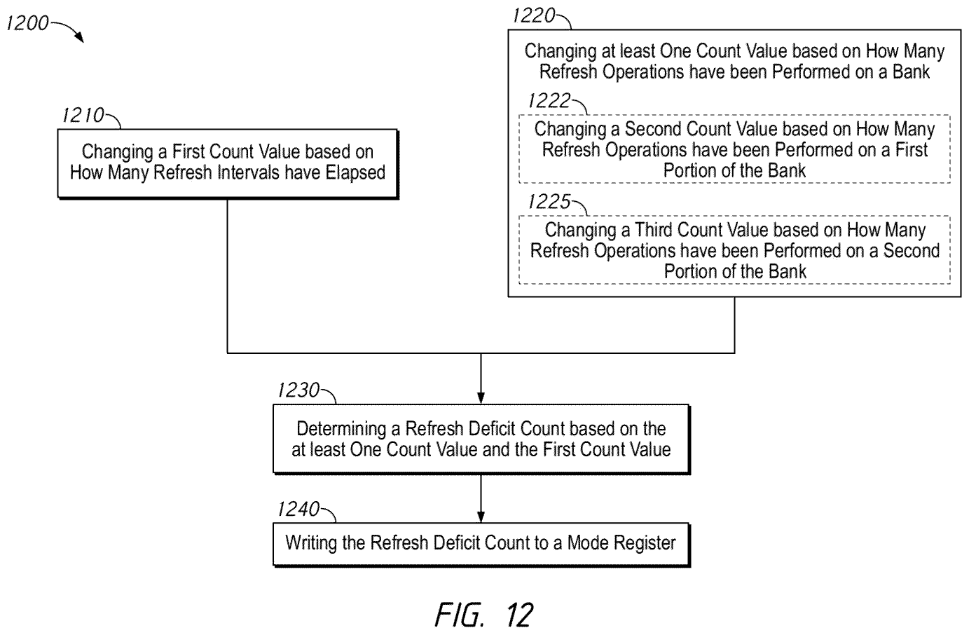

The refresh control circuit 116 writes its refresh deficit count DeficitCnt 134 to the mode register 130. A controller may perform mode register read (MRR) operations to read the values of the refresh deficit counts DeficitCnt for each of the banks from the mode register 130. The refresh control circuits 116 may use set timing, for example based on tREFIcnt, to determine when to write the current values of the refresh deficit counts 134 to the mode register 130. An example of how and when the mode register values may be written and read is described in more detail in FIGS. 12-14.

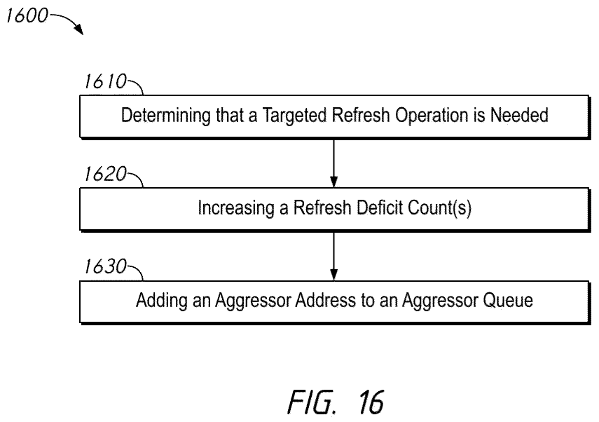

The refresh control circuit 116 also tracks accesses to word lines of the respective banks to determine if a targeted refresh operation should be performed. Memory cells along each word line are set aside as counter memory cells 126. The counter memory cells store an access count associated with a number of times that the respective word line has been accessed. When a word line is accessed or refreshed, its count is read out to the refresh control circuit 116 which updates (e.g., increments) the count value and determines if the count has crossed a threshold. If the count has crossed a threshold, then the address is added to an aggressor queue for a later targeted refresh operation. When a targeted refresh operation is performed, one or more victim word lines of the aggressor word line are refreshed. In some embodiments, the refresh control circuit 116 may check the aggressor queue as well as the refresh deficit count 134 when determining whether or not to perform a refresh operation responsive to a refresh opportunity. In some embodiments, the refresh control circuit 116 may update the refresh deficit count DeficitCnt 134 based on the state of the aggressor queue. An example embodiment where the aggressor queue is used to update the deficit count is described in more detail in FIG. 16.

The power supply terminals are supplied with power supply potentials VDD and VSS. The power supply potentials VDD and VSS are supplied to an internal voltage generator circuit 224. The internal voltage generator circuit 224 generates various internal potentials VARY, and the like based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 222. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

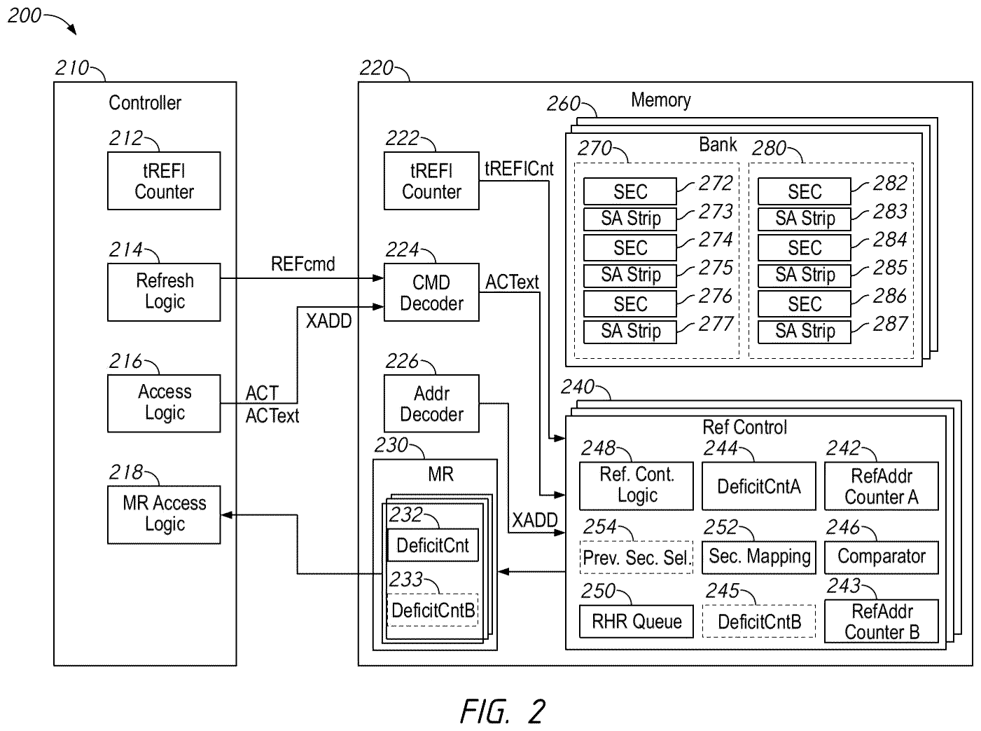

FIG. 2 is a block diagram of a memory system according to some embodiments of the present disclosure. The memory system 200 of FIG. 2 includes a controller 210 and a memory device 220. The memory device 220 of FIG. 2 may, in some embodiments, be implemented by the memory device 100 of FIG. 1. For the sake of brevity, certain components, signals, and operations already described with respect to FIG. 1 will not be repeated with respect to FIG. 2. Although the memory system 200 illustrated in FIG. 2 is shown with one memory device 220, it will be appreciated that a memory system according to some embodiments of the disclosure may include several memory devices 220, with the controller 210 communicating and operating with the several memory devices.

The controller 210 includes a refresh period counter 212 which counts a number of elapsed refresh periods, analogous to the refresh period counter 140 of FIG. 1. The controller 210 also includes a refresh logic circuit 214 that determines when to send refresh commands REFcmd and includes an access logic circuit 216 that determines when to send access commands and whether or not to send access command which have an extended timing window or not. The controller 210 also includes a mode register access logic circuit 218. The mode register access logic circuit 218 determines when to access the refresh deficit counts 232 (and optional second refresh deficit count 233) in a mode register 230 of the memory 220. For example, the mode register access logic circuit 218 may perform a mode register read operation to retrieve the deficit count(s) from the mode register 230.

In some embodiments, rather than use mode register read operations, the deficit counts may be provided via a sideband bus. For example, multiple memory devices 220 may be packaged onto a module and organized into channels. For each channel, one of the memory die is designated as a primary memory die and collects the refresh deficit counts for all of the other memory die of that channel. The controller accesses that information via a sideband communication to collect the refresh deficit counts from the memory devices 220 of that channel.

The memory 220 includes a refresh period counter 222 (e.g., 140 of FIG. 1) which is analogous to the refresh period counter 212 in the controller 210. The memory 220 also includes a command decoder 224 (e.g., 106 of FIG. 1), address decoder 226 (e.g., 104 of FIG. 1), mode register 230 (e.g., 130 of FIG. 1), memory array 260 (e.g., 118 of FIG. 1), and a refresh control circuit 240 (e.g., 116 of FIG. 1). The command decoder 224 and address decoder 226 receive commands and addresses respectively and provide them to the other components of the memory 220. The bank 260 includes a number of word lines organized into sections such as 272, 274, 276, 282, 284, and 286. The bank also includes a number of sense amplifier strips such as 273, 275, 277, 283, 285, and 287 which include the sense amplifiers coupled to the bit lines of the neighboring sections. In some embodiments, the bank 260 may be organized into a first portion 270 and a second portion 280, each include a portion of the sections and sense amplifiers. While 6 sections and sense amplifier strips are shown in FIG. 2, more or fewer sections and sense amplifier strips may be used in other example embodiments.

The refresh control circuit 240 associated with a bank 260 determines if there is a refresh opportunity based on the command, address, or combinations thereof, and determines if a refresh is required. If a refresh is required and the refresh opportunity is a stand-alone refresh opportunity, the refresh control circuit 240 performs one or more stand-alone refresh operations. If the refresh is required, and the refresh opportunity is a background refresh opportunity, the refresh control circuit 240 determines if a background refresh is possible, for example based on the section being accessed. If a background refresh is possible, the refresh control circuit 240 performs a refresh operation for memory of the respective memory bank.

The refresh control circuit 240 includes a first refresh address counter 242 and a second refresh address counter 243 (e.g., 132 of FIG. 1) each associated with a respective portion of the bank 270 or 280 respectively. The refresh control circuit 240 also includes a refresh deficit counter 244 (e.g., 134) based off the first refresh address counter 242 and the second refresh address counter 243. In some embodiments, the refresh control circuit 240 includes an optional previous section select bit latch 254. In some embodiments, two refresh address counts from the counters 242 and 243 are compared and a lower value of the two address counts is used to determine the refresh deficit count 232. In some embodiments, there may be an optional second deficit count 233, and each refresh address counter 242 and 243 is associated with a respective one of the two deficit counts 244 and 245. The refresh deficit counts 244 is used to update corresponding value 232 in the mode register 230, where they may be accessed by the controller 210. In embodiments with two deficit counts 244 and 245, there may also be two corresponding deficit counts 232 and 233 in the mode register 230. While two refresh address counters 242/243, two deficit counts 244/245 and two deficit mode registers 248/250 are shown in FIG. 2, more counters may be used in other example embodiments. In some embodiments, there may be any numbers of refresh counters, each associated with a respective portion of the bank 260. For example three refresh counters each associated with a third of the bank 260, four refresh counters each associated with a quarter of the bank 260 and so forth.

The controller 210 performs access operations on the memory 220 by providing commands, addresses, and in the case of write operations data, to the memory 220. In some example embodiments, the controller 210 can provide a first type of access command or a second type of access command. The access command may include one or more individual commands such as an activation command, pre-charge command, and read or write command. An example access operation includes providing an activation command ACT, waiting a row activation time tRAS, and then providing a pre-charge command PRE. After providing PRE, the controller waits a pre-charge time tRP before a next activation command may be provided. One or more of those commands may specify a timing window of the access command, or of a subsequent access command.

The first type of access command has a first timing window while the second type of access command has a second timing window which is longer than the first timing window. For example, the first type of access command may have a first pre-charge time tRP_S, while the second type of access command may have a second pre-charge time tRP_L. In some embodiments, the controller 210 may provide a access command which includes a first type of activate command ACT to indicate the first timing window or an access command which includes a second type of activate command ACText to indicate the second timing window. The first type of activate command ACT may be referred to as a normal activate command and the second type of activate command ACText may be referred to as an extended activate command. In some example embodiments, one of the C/A terminals may be used to mark the difference between and ACT and ACText. Other forms of conveying the timing window, and other commands to signal the timing window, may be used in other example embodiments. In some embodiments, the timing window may be adjusted automatically by the controller 210 and memory 220 based on a comparison of a section select bit of the row address to a section select bit from the row address of the previous access command.

After sending the first type of access command (e.g., with ACT), the access logic 216 may wait a first period of time before sending a next access command. After sending the second type of access command (e.g., with ACText), the access logic 216 may wait a second period of time before sending a next access command. The two different periods of time may be based on different lengths of pre-charge times tRP_S or tRP_L associated with the different types of access command. The difference between the first period of time and the second period of time may be an extension time tRPext which is the difference between tRP_L and tRP_S. The access logic 216 may determine when to send the first or the second type of access command. For example, the access logic circuit 216 may generally default to sending the second type of access command unless the controller 210 is busy, such as when a queue of pending access operations is beginning to fill.

In some embodiments, the access timing may be determined based on one or more section select bits of the row address. For example, the bank 260 may be divided into a first portion 270 and a second portion 280, a section select bit, such as an MSB, of the row address specifies whether the row address is associated with a word line in the first portion 270 or the second portion 280. If the address XADD is in a same portion as the previous access operation, then the first period of time, tRP_S may be used. If the address is in a different portion as the previous access operation, then the second period of time tRP_L may be used. The access logic circuit 216 may monitor the state of the section select bits and determine which timing to use in sending access operations. The memory 220 may also monitor the state of the section select bits and determine which timing to expect. In some embodiments, the timing windows may be entirely based on the section select bits, and the second time of access command may not be used.

The refresh logic 214 of the controller 210 determines when to provide refresh commands REFcmd based on the deficit count 232 in the mode register 230. The mode register access logic circuit 218 may periodically check the values of the deficit count 232 by performing mode register read (MRR) operations on those registers, each associated with a different bank. The period at which the deficit counts are checked may be based on the refresh interval count maintained by the refresh interval counter circuit 212 of the controller. In some embodiments, the mode register access logic 218 may have certain scheduled values of the refresh interval count on which it checks the deficit count values 232 and 233. An example of timing used to check the mode register 230 is described in more detail in FIGS. 12-14.

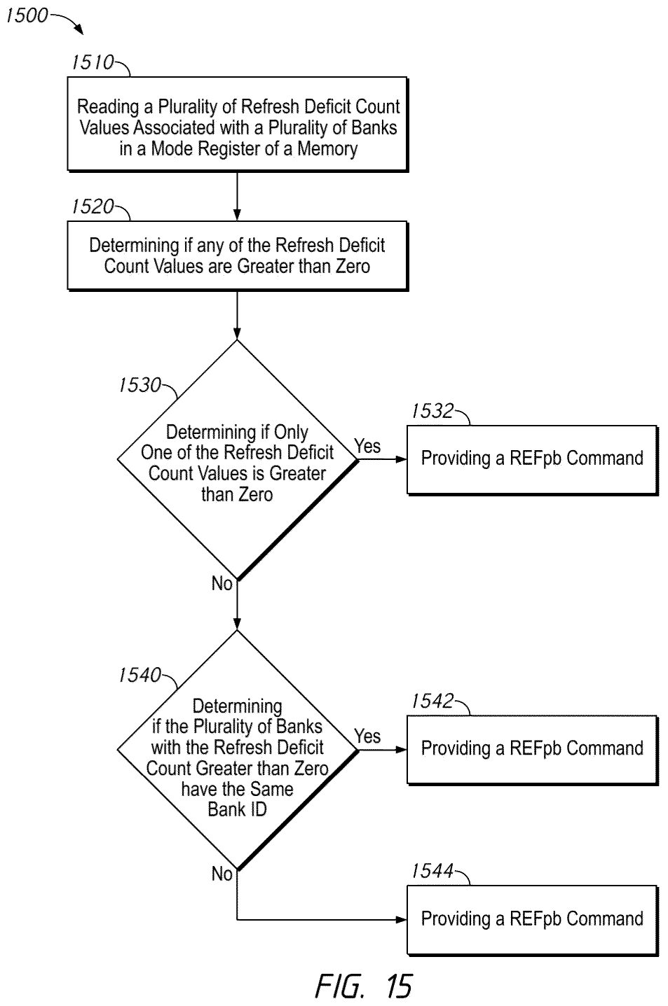

The refresh logic 214 receives the updated deficit count 232 when the mode register access logic circuit 218 checks them and uses those values to determine if a refresh command should be provided and what type of refresh command. In the example implementation of FIG. 2, the refresh logic 214 receives a count 232 for each bank 260 of the memory device 220. If any of the counts is non-zero, the refresh logic 212 may provide a refresh command REFcmd. In some embodiments, the refresh logic 214 may provide a type of refresh command based on how many banks, and which banks, have a non-zero refresh deficit count. An example of how the refresh logic circuit 214 determines when and what type of refresh commands to provide is explained in more detail in FIG. 15.

The memory device 220 determines an opportunity for a refresh operation based on the commands, addresses, or combinations thereof provided by the controller. For example, the refresh command REFCmd may be an opportunity for a stand-alone refresh operation. An access command, such as an access command which allows for ACText, and extended activation time with tRP_L, may be an opportunity for a background refresh operation. In some embodiments, any access may be an opportunity for a background refresh opportunity, and a state of the section select bit compared to a previous section select bit may be used to determine the timing of the access operation and, if performed, background refresh operation.

When a bank 260 is given a refresh opportunity, either background or stand-alone, the refresh control circuit 240 associated with that bank determines if a refresh operation is required based on the deficit count 244 and if so and if the opportunity is for a background refresh, determines if a refresh operation is possible. For example, when a word lines are accessed, it may be impossible to perform a background refresh on certain other word lines based on their location relative to the accessed word line.

The refresh interval counter 222 generates a refresh interval count tREFIcnt which is shared by all the refresh control circuits 240. The refresh interval count tREFIcnt counts a number of refresh periods which have elapsed in the current refresh period.

In the example of FIG. 2, the refresh control circuit 240 includes two refresh address counters 242 and 243. More or fewer refresh address counters may be used in other example embodiments. Each of the refresh address counters tracks refresh operations, and generates refresh addresses for, different portions of the bank 260. The first refresh address counter 242 may be associated with the first portion 270 and the second refresh address counter may be associated with the second portion 280. For example, the first refresh address counter 242 generates refresh addresses for a first half of the word lines in the bank 260 in the first portion 270 and the second refresh address counter 243 generates refresh addresses for a second half of the word lines in the bank 260 in the second portion 280. The refresh control circuit 240 includes a comparator circuit 246. The comparator circuit 246 compares the values of the two refresh address counters 242 and 243 to determine which counter has a lower value. The lower of the two refresh address counter values is compared to the refresh interval count tREFIcnt to generate the value of the refresh deficit count 244. In embodiments with multiple refresh address counters, the comparator circuit 246 may adjust the value of the refresh address counts, tREFIcnt or combinations thereof, to take the number of refresh address counters into account. For example, the comparator circuit 246 may halve tREFIcnt before comparing it to the lower of the two refresh address counts. In some embodiments, the values of both refresh address counters 242 and 243 are separately compared to the refresh interval count tREFIcnt to generate separate refresh deficit counts 244 and 245.

The memory device 220 includes a number of banks 260. In the example of FIG. 2, each bank is divided into two portions, 270 and 280. Each portion 270 or 280 may include about half of the word lines and memory cells of the bank 260. In the example illustration of FIG. 2, the two portions 270 and 280 are shown side-by-side, however any organization of the portions may be used in other example embodiments. For example, in some embodiments, the portions 270 and 280 may represent alternating sections, such as even numbered sections and odd numbered sections. In some embodiments, the portions 270 and 280 may represent a top and bottom portion of the sections, for example portion 270 may be section0 to sectionA-1 and the portion 280 may be sectionA to sectionB-1 where there are B total sections and A is half of B. Other organizations of the portions 270 and 280 may be used in other example embodiments.

The word lines are shown organized in sections such as sections 272, 274, and 276 in the first portion 270 and sections 282, 284, and 286 in the second portion 280. While only three sections are shown in each portion 270 and 280 in the example of FIG. 2, any number of sections may be provided in other examples. Each section is bordered by two sense amplifier strips such as 273, 275, 277, 283, 285, and 287. Accordingly, each sense amplifier strip has two neighboring sections. For example, sense amplifier strip 273 is between sections 272 and 274, sense amplifier strip 275 is between sections 274 and 276 and sense amplifier strip 277 is next to section 276. Each sense amplifier strip includes sense amplifiers with two inputs, each coupled to a bit line in each of the adjacent sections. So, for example, a sense amplifier in the strip 273 would be coupled to a bit line in section 272 and a bit line in section 274.

When a word line is accessed, certain sections may be off-limits for a background refresh operation. For example, when a section is being accessed, the sections adjacent to that section, as well as the sections adjacent to those sections, may be off-limits. For example if SectionN is accessed, then SectionN−2 to SectionN+2 may all be off-limits. In some embodiments, the organization of the portions 270 and 280 may affect how the off-limits sections are distributed. For example, if a section in the first portion 270 is accessed, then it may only restrict access to a section in the second portion 280 if the section in the first portion 270 is at an edge of the first portion 270.

The refresh control circuit includes a refresh control logic circuit 248. The refresh control logic circuit 248 manages determining if there is an opportunity for performing a refresh operation, and whether or not to perform refresh operation if given the opportunity. For example, if the refresh control logic circuit 248 receives an access command which includes an extended activation command ACText for that bank, then the refresh control logic circuit 248 may check the refresh deficit count 244. If the deficit count 244 has a non-zero value, the refresh control logic circuit 248 checks the current values of the refresh address counters 242 and 243 against a section mapping logic circuit 252 to determine if either or both of them are possible to use as part of a refresh address. The section mapping logic circuit 252 receives the row address XADD which is being accessed and determines the sections where a background refresh cannot be performed (e.g., SectionN-2 to SectionN+2). If at least one of the refresh address counters has a current value associated with a refresh address it is possible to use for background refresh, then the refresh control logic circuit 248 performs a background refresh. If both refresh counters have a value associated with refreshable addresses, then the refresh control logic circuit 248 selects between them, for example by selecting the refresh address counter 242 or 243 with the lower value.

In some embodiments, the controller 210 may use the sequence of row addresses provided as part of access operations to determine a timing of the access operation. For example, the access operation may be performed on one of the portions 270 and 280, and the background refresh operation may be performed in the other of the portions 270 and 280.

During a background refresh operation, the refresh control circuit 240 generates a refresh address based on the selected refresh address counter 242 or 243. The refresh control logic circuit 248 selects one of the refresh address counters 242 or 243 based on the value of the counters, the value of the section select bit of the current row address, or combinations thereof. The row decoder (e.g., 108 of FIG. 1), not shown in FIG. 2, accesses the row associated with XADD in a first section, and refreshes the word line associated with the refresh address in a second section. The accessed word line and the refreshed word line may be active at overlapping periods of time. In some embodiments, the time at which the row is accessed and the time at which the row is refreshed may be offset from each other, but of the same length. For example, the row decoder may activate the accessed row at a first time and activate the refreshed row at a second time. Responsive to performing the refresh operation, the refresh address counter 242 or 243 used to generate the refresh address is updated, for example by being incremented. In another example, when a word line is determined to be an aggressor row, the deficit count 244 may be increased to indicate that a refresh operation for victim rows is needed in order to mitigate effects caused by the aggressor row.

In some embodiments, the refresh control circuit includes a targeted refresh queue 250. In some embodiments, the refresh control logic circuit 248 may use a state of the targeted refresh queue to determine when to perform a refresh operation. For example, if the deficit count 244 is zero, the refresh control logic circuit 248 may check the targeted refresh queue, and if the targeted refresh queue is non-empty, perform a targeted refresh operation as the background refresh operation. In some embodiments, the state of the targeted refresh queue 250 may be used to modify the deficit counts 244. For example, the deficit count 244 may be increased if the targeted refresh queue is non-empty.

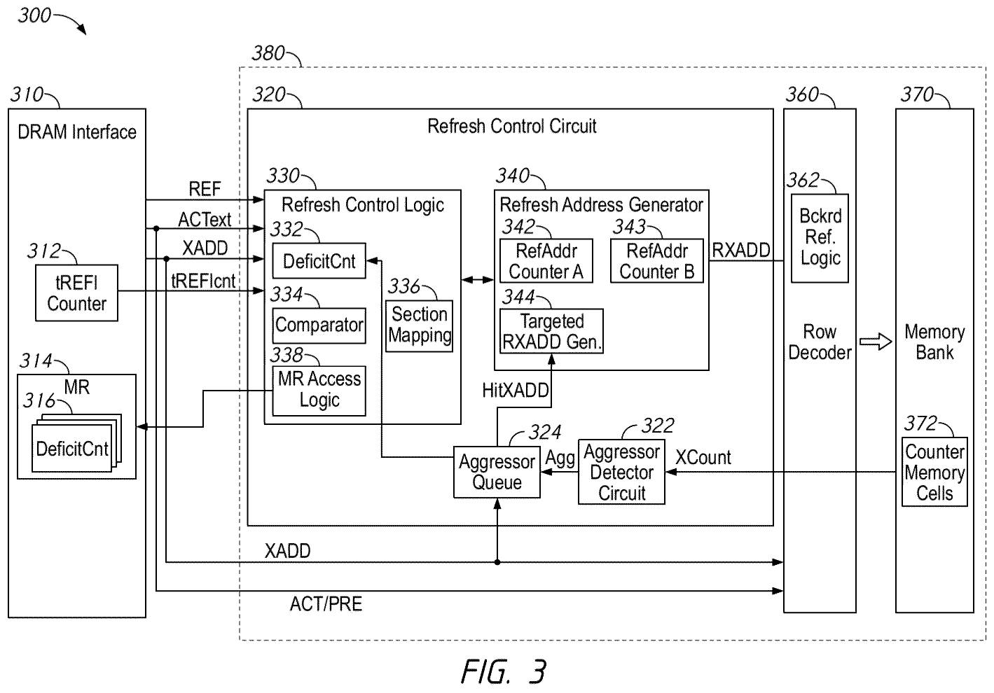

FIG. 3 is a block diagram of a memory device according to some embodiments of the present disclosure. The memory device 300 of FIG. 3 may, in some embodiments, be included in the memory device 100 of FIG. 1, the memory device 220 of FIG. 2, or combinations thereof. The memory device 300 of FIG. 3 shows a simplified view of a memory device focusing on the refresh control circuit 320 (e.g., 116 of FIG. 1, 240 of FIG. 2, or combinations thereof). For the sake of brevity certain signal lines and components are omitted from the view of FIG. 2. Also for the sake of brevity certain signals, operations, and components already described with respect to FIG. 1 or FIG. 2 will not be described again with respect to FIG. 3.

The memory device includes a DRAM interface 310, the refresh control circuit 320, a row decoder 360 (e.g., 108 of FIG. 1), and a memory bank 370 (e.g., 118 of FIG. 1, 260 of FIG. 2, or combinations thereof). A box 380 is shown around the refresh control circuit 320, row decoder 360, and memory bank 370 to represent that those components are repeated on a bank-by-bank basis. The deficit counts 316 in the mode register 314 are also repeated on a bank-by-bank basis, such as one stored refresh deficit count for each memory bank 370. The refresh control circuit 320 includes a refresh control logic circuit 330, a refresh address generator 340, an aggressor detector circuit 322, and an aggressor queue 324. The refresh control logic circuit 330, which may perform the functions of the refresh control logic circuit 248 of FIG. 2, is shown in FIG. 3 as including a refresh deficit count 332 (e.g., 134 of FIG. 1, 244/245 of FIG. 2, or combinations thereof), a comparator circuit 334 (e.g., 246 of FIG. 2), a section mapping circuit 336 (e.g., 252 of FIG. 2), and a mode register access logic circuit 338. The refresh address generator circuit 340 includes a first refresh address counter 342 and a second refresh address counter 343 (e.g., 132 of FIG. 1, 242/243 of FIG. 2, or combinations thereof) as well as a targeted refresh address generator 344.

The DRAM interface 310 represents various components of the memory device 300 which communicate with the refresh control circuit 320. For example, the DRAM interface 310 includes components such as the command/address input circuit (e.g., 102 of FIG. 1), the address decoder (e.g., 104 of FIG. 1, 226 of FIG. 2, or combinations thereof), and the command decoder (e.g., 106 of FIG. 1, 224 of FIG. 2, or combinations thereof). The DRAM interface 310 is shown as including the refresh interval counter circuit 312 (e.g., 140 of FIG. 1, 222 of FIG. 2, or combinations thereof) and a mode register 314 (e.g., 130 of FIG. 1, 230 of FIG. 2, or combinations thereof). The mode register 314 stores a refresh deficit count 316 (e.g., 134 of FIG. 1, 232/233 of FIG. 2, or combinations thereof) for each of the memory banks 370.

When an access operation is performed, the DRAM interface 310 provides signals such as the row activation signal ACT and a row address XADD. The refresh control logic circuit 330 determines if the command (e.g., ACT), address, or combinations thereof represent a background refresh opportunity. For example, if the activation signal is an extended activation signal ACText, the refresh control logic circuit 330 may determine that to be an opportunity for a background refresh. If there is an opportunity for a background refresh, the refresh control logic circuit 330 checks the refresh deficit counter 332. If the refresh deficit counter 332 is non-zero, then the refresh control logic checks the associated refresh address counters 342 and 343 to determine if a background refresh is possible. The refresh control logic 330 checks the current values of the refresh address counters against the row address XADD using the section mapping logic circuit 336 to determine if either or both of the refresh addresses is in a section where a background refresh can be performed. If both are possible, then the refresh address counter with the lower value is chosen. That is, the background refresh operation is performed in the section with fewer refreshes for the current refresh period (and in need of more refresh operations).

The row decoder 360 includes background refresh logic 362. Responsive to an access operation, the row decoder 360 activates a first word line in a first section at a first time for the access operation. If a background refresh operation is being performed, then at a second time, which is a delay time after the first time, the background refresh logic 362 activates a second word line in a second section. At a third time the first word line being accessed is deactivated or pre-charged, and at a fourth time after the third time the second word line being refreshed is pre-charged. The first word line is accessed while the second word line is refreshed. In some embodiments, the delay time may be tRPext, the difference between a regular and extended activation period. In some embodiments, the delay time may be zero and both word lines may be activated at the same time.

The memory 300 may receive a refresh command from a controller (e.g., 210 of FIG. 2) which specifies one or more banks. The DRAM interface 310 provides a refresh signal REF to the refresh control circuit(s) 320 of the specified bank(s). The refresh signal may act as an indication of an opportunity for a stand-alone refresh operation. Responsive to the refresh signal REF, the refresh control logic 330 determines whether or not to perform one or more refresh operations. For example, if the deficit counter 332 is non-zero, a refresh operation may be performed. Unlike a background refresh, since no word line is being accessed, it is not necessary to use the section mapping logic 336 to determine if it is possible to refresh the addresses. Responsive to the refresh signal REF the refresh control logic circuit 330 may perform multiple refresh operations. For example, the refresh control logic 330 may generate one or refresh activation cycles and perform a refresh operation on each refresh activation cycles.

When a refresh is performed, the appropriate refresh counter 342 or 343 is updated (e.g., incremented). The comparator 334 uses the current values of the refresh counters 342 and 343 as well as the refresh interval count tREFIcnt to update the value of the refresh deficit counter 332. For example, the comparator 334 compares the value of the two refresh address counters 342 and 343, and the lower of those two values is compared to tREFIcnt. If the lower address value is greater than or equal to tREFIcnt, the refresh deficit counter 332 is set to zero. If the lower address value is less than tREFIcnt, then the refresh deficit counter 332 is set to the difference of tREFIcnt and the address count. In some embodiments, before comparing tREFIcnt to the address count values, the refresh interval count may be adjusted, for example by being divided by two. The mode register access logic circuit 338 determines when to write the current value of the refresh deficit count 332 to the mode register 314 as the value 316.

The mode register access logic circuit 338 may periodically write the current value of the deficit count 332 to the mode register 314. The period may be set based, in part, on the refresh interval tREFI. For example, the mode register access logic 338 may use the value of the tREFIcnt to determine when to write the value of the refresh deficit count 332 to the mode register 314. In some embodiments, the mode register access logic circuit 338 is set to write the value to the mode register 314 at times when the controller is not reading the mode register 314. For example, the mode register access logic 338 may be set to write on different values of tREFIcnt than the mode register access logic (e.g., 218 of FIG. 2) of the controller.

The memory bank 370 includes a number of counter memory cells 372 (e.g., 126 of FIG. 1) used to store access counts. The access counts may be used as part of per-row access counting (PRAC) in order to manage targeted refresh operations. When a word line is accessed or refreshed, the access count from the counter memory cells along that word line is read out to the aggressor detector circuit 322. If the word line is being refreshed, the access count is reset to an initial value (e.g., 0). If the word line is being accessed, the aggressor detector circuit 322 updates the access count value and determines if the word line is an aggressor. If the word line is an aggressor, the address associated with the word line is added to the aggressor queue 324 and the access count value is reset. The updated count value or the reset count value is then written back to the counter memory cells 372. In some embodiments, the aggressor detector circuit 322 may additionally or alternatively modify the deficit count 332 when the aggressor detector circuit 322 determines a word line is an aggressor. For example, when the aggressor detector circuit 322 determines a word line is an aggressor, the aggressor detector circuit 322 causes the deficit count 332 to increase. The increase in the deficit count 332 indicates a targeted refresh operation should be performed for victim rows of the aggressor word line. The address associated with the aggressor word line, which is added to the aggressor queue 324, as previously described, may be used to provide the addresses of the victim rows to be refreshed. By using the deficit count 332 to indicate when a targeted refresh operation is needed, management of targeted refresh operations is integrated with other refresh operations for more efficient refresh management.

In some embodiments, the aggressor detector circuit 322 may be shared by the counter memory cells of the bank 372 and may not be able to handle more than one count value at a time. To prevent conflicts, the background refresh logic 362 may stagger the timing of activating a word line as part of an access operation and activating a word line as part of a background refresh operation. For example, the row decoder 360 may activate the first word line as part of the access operation, and then when the aggressor detector is updating the access count value of the first word line, activate the second word line as part of the background refresh operation. By the time the access count value for the second word line is read out to the aggressor detector circuit 322, the aggressor detector circuit 322 is already done with the access count value of the first word line.

In an example implementation, when a word line is activated, the corresponding access count value is read from the counter memory cells 372 to the aggressor detector circuit 322. The aggressor detector circuit 322 updates the access count value, for example, by incrementing the access count value. The updated access count value is compared to a threshold. If the updated access count value has not crossed the threshold, it is written back to the counter memory cells 372. If the updated access count value has crossed the threshold, then the aggressor detector circuit 322 resets the access count value to an initial value such as 0, provides an aggressor detected signal Agg and writes the reset access count value back to the counter memory cells. Responsive to the signal Agg, the current address, either XADD or RXADD is added to the aggressor queue 324. As previously described, in some embodiments, the aggressor detector circuit 322 may also modify the first deficit count 332 when the aggressor detector circuit 322 determines a word line is an aggressor word line. For example, when the access count value for a word line has crossed the threshold, the aggressor detector circuit 322 may also provide the aggressor detected signal Agg to the refresh control logic 330 to increase the first deficit count 332. The increase in the first deficit count 332 indicates that there is at least one refresh deficit for a targeted refresh operation of victim rows of the aggressor word line.

The aggressor queue 324 includes a number of storage elements, such as latch circuits. The aggressor queue 324 stores addresses. The aggressor queue 324 acts as an ordered queue, such as a FIFO queue. When a targeted refresh operation is performed, the aggressor queue provides a stored address HitXADD and removes that address from the queue 324.

During a targeted refresh operation, the targeted refresh address generator 344 uses the address HitXADD from the queue 324 to generate one or more refresh addresses. For example, the targeted refresh address generator 344 may generate refresh addresses which are adjacent to the address HitXADD (e.g., RXADD=HitXADD+/−1). Other relationships (e.g., RXADD=HitXADD+/−2,+/−3, etc.) may be used in addition or instead.

In some embodiments, the refresh control logic 330 may wait to perform a targeted refresh operation until a refresh command is received and the signal REF is provided. In some embodiments, the refresh control logic 330 may check the state of the aggressor queue 324 and perform a targeted refresh as a background refresh when an aggressor is available to be refreshed. For example, the refresh control logic circuit 330 may check the refresh deficit count 332, and if it is zero, check the status of the refresh address queue 324. If the refresh address queue is not empty, a targeted refresh may be performed as a background refresh operation. In some embodiments, the deficit count 332 may be used to indicate that a targeted refresh is needed, such as when the deficit count 332 is modified (e.g., increased) when a word line is determined to be an aggressor by the aggressor detector circuit 322, as previously described. Increasing the deficit count 332 adds at least one refresh operation to be performed that can be used for a targeted refresh, which can be handled by the refresh control logic 330 as a stand-alone refresh operation for a refresh command or as a background refresh for an access command with extended activation.

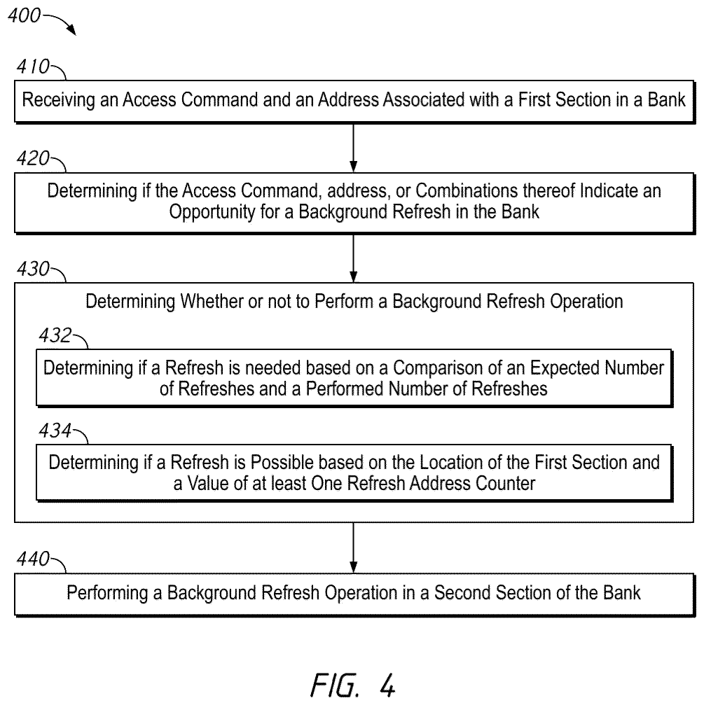

FIG. 4 is a flow chart of a method of performing background refresh operations according to some embodiments of the present disclosure. The method 400 may be implemented by one or more of the apparatuses or systems described herein. For example, the method 400 may be implemented by the memory device 100 of FIG. 1, 220 of FIG. 2, 300 of FIG. 3, or combinations thereof.

The method 400 may generally begin with box 410 which describes receiving an access command (which may include an activation command) and an address associated with a first section in a bank. The access command and address may be received by a command address input circuit (e.g., 102 of FIG. 1) along one or more command/address input terminals. The address may be a row address (e.g., XADD) which specifies a word line in the first section. The access command may include an activation command, a pre-charge command, and a read or a write command.

Box 410 is generally followed by box 420, which describes determining if the access command, the address, or combinations thereof, indicate an opportunity for a background refresh in the bank. For example, box 420 may include determining if there is an extended timing window (e.g., tRP_L) associated with the access command. In some embodiments, one of the CA terminals may be used to determine if the activation command is extended or not (e.g., ACText). The box 420 may include determining if the extended activation signal is active, indicating an extended timing window. Other methods of determining if there is a background refresh opportunity may be used in other example embodiments. For example, in some example embodiments, each access command may represent a background refresh opportunity, and the section select bits of the row address may indicate if there is an extended timing window or not. If there is not an opportunity to perform a background refresh operation, the method 400 may generally end at box 420. If there is an opportunity to perform a background refresh operation, the method 400 continues to box 430.

If there is a background refresh opportunity, box 420 is generally followed by box 430, which describes determining whether or not to perform a background refresh operation. For example, box 430 may include boxes 432 and 434. Box 432 describes determining if a refresh is needed. Box 432 may include determining if the refresh is needed based on a comparison of an expected number of refreshes to a performed number of refreshes. The method 400 may include determining the expected number of refreshes based on a count of refresh intervals (e.g., tREFIcnt). The method 400 may include determining the performed number of refreshes based on the refresh address counter (e.g., 132 of FIG. 1, 242/243 of FIG. 2, 342/343 of FIG. 3, or combinations thereof).

In some embodiments, the method 400 may include setting a refresh deficit count value (e.g., 134 of FIG. 1, 244/245 of FIG. 2, 332 of FIG. 3, or combinations thereof) based on the comparison. The method 400 may include determining that a refresh is needed based on a value of the refresh deficit count. For example, the method 400 may include setting the value of the refresh deficit count to 0 if the number of performed refresh operations is equal to or greater than the number of expected refresh operations and setting the value of the refresh deficit to the difference between the expected and performed refresh operations if there are more expected than performed refresh operations. In some embodiments, the first refresh deficit count and/or the second deficit count may be modified when a word line has been determined to be an aggressor word line. The modified refresh deficit count may indicate a need for a refresh operation to be used for targeted refresh of victim rows of the aggressor word line.

In some embodiments, the method 400 may include determining that a refresh is needed if the refresh deficit count is non-zero. In some embodiments, other conditions may be used to determine if a refresh is needed. In some embodiments, the method 400 may include determining that a refresh is needed even if the deficit count is zero. For example, box 430 may include determining to perform a refresh even if the deficit count is zero while a background refresh counter is below a background refresh threshold and if a background refresh is performed, changing (e.g., incrementing) the background refresh counter. If the refresh deficit count becomes non-zero, the background refresh counter is reset. In this manner, even if the refresh deficit count is zero, the method 400 may include performing up to the background refresh threshold number of background refresh operations. This may allow the memory device to get ahead of the expected number of refreshes.

In some embodiments, the method 400 may include setting the refresh deficit count value based on a first refresh address count value and a second refresh address count value. The first refresh address count value is generated by a first refresh address counter associated with a first portion of the bank and the second refresh address count value is generated by a second refresh address counter associated with a second portion of the bank. The method 400 may include comparing the first and the second refresh address count values and using a lower of the two to determine the refresh deficit count value. In some embodiments, the method may include adjusting the refresh interval count based on the number of refresh address count values. For example, if there are two refresh address counters, the method may include dividing the refresh interval count value in half.

Box 430 includes box 434 which describes determining if a refresh is possible. For example box 434 may include determining if a refresh is possible based on the location of the first section, and a value of at least one refresh address counter (e.g., 132 of FIG. 1, 242/243 of FIG. 2, 342/343 of FIG. 3, or combinations thereof). For example, the method 400 may include determining, with a section mapping circuit (e.g., 252 of FIG. 2, 336 of FIG. 3, or combinations thereof), which sections of the bank cannot have a background refresh performed during this access operation based on the location of the first section, and if the word line associated with the value of the at least one refresh counter is in one of the sections which cannot have a background refresh performed.

If box 430 determines not to perform a background refresh operation, either because no refresh is needed, no refresh is possible, or both, then the method 400 may end with box 430. If box 430 determines to perform a background refresh operation, because a refresh operation is both needed and possible, then the method 400 proceeds to box 440.

Box 440 describes performing a background refresh operation in a second section of the bank. The second section is different than the first section. In some embodiments, the method 400 may include performing the access operation on a word line of the first section of the bank over a first time period and performing a refresh operation on a word line of the section of the bank over a second time period which has at least some overlap with the first time period. In some embodiments, the method 400 may include offsetting the first time period from the second time period. The method may include selecting the word line in the second section based on the value of the at least one refresh address counter. The method 400 may include updating (e.g., incrementing) the value of the at least one refresh address counter responsive to performing the background refresh operation.

In some embodiments, the method 400 may include determining if word line is an aggressor word line. For example, the method 400 may include updating access counts in counter memory cells (e.g., 126 of FIG. 1, 372 of FIG. 3, or combinations thereof) with an aggressor detector circuit (e.g., 324 of FIG. 3). The method 400 may include adding an aggressor address associated with the aggressor word line to an aggressor queue (e.g., 250 of FIG. 2, 324 of FIG. 3, or combinations thereof). The method 400 may include performing a targeted refresh operation on a targeted refresh address generated from the aggressor address. For example, box 432 may include determining that a refresh is needed if at least one address is in the aggressor queue. The method 400 may include determining to perform a targeted refresh if there is at least one address in the aggressor queue but the refresh deficit counter is zero. Box 440 may include performing a targeted refresh operation as a background refresh operation. In some embodiments, refresh deficit counts may be used to indicate that a targeted refresh is needed.

FIG. 16 shows a flow chart of a method 1600 of indicating the need for a targeted refresh operation according to some embodiments of the present disclosure. The method 1600 may be implemented by one or more of the memory devices, memory controllers, or combinations thereof, such as the memory device 100 of FIG. 1, memory device 220 and/or controller 210 of FIG. 2, memory device 300 of FIG. 3, or combinations thereof.

The method 1600 may generally begin with a box 1610 which describes determining that a targeted refresh operation is needed. A targeted refresh operation may be needed, for example, when a word line is determined to be an aggressor word line. In some embodiments, a word line may be determined to be an aggressor word line based on an access count of the word line, for example, the access count of the word line exceeds a threshold. An aggressor detector circuit, such as 322 of FIG. 3, may determine if the word line is an aggressor based on the access count. The access count exceeding the threshold may suggest that the word line has been repeatedly accessed to the extent that it may cause accelerated degradation of the data stored by memory cells of victim word lines (e.g., word lines physically proximate to the aggressor word line). Using a threshold for access accounts is described by way of example. Other techniques for determining that a targeted refresh operation is needed and for determining that a word line is an aggressor word line may be used without departing from the scope of the present disclosure.

Box 1610 is generally followed by box 1620, which describes modifying refresh deficit counts by increasing first and/or second deficit counts. By increasing the deficit counts, at least one refresh operation that will be performed to erase any refresh deficit can be used for a targeted refresh of victim word lines. For example, where the first deficit count is a number X, the first deficit count may be increased to X+1 when a word line is determined to be an aggressor word line at box 1610. The first deficit count represents X refreshes that may be needed to catch up to an expected number of refreshes, and further represents an additional 1 refresh that may be used for a targeted refresh.

Box 1620 may be optionally followed by box 1630, which describes adding an aggressor address associated with the aggressor word line to an aggressor queue. The aggressor address added to the aggressor queue is used to provide addresses corresponding to victim rows that are refreshed when a targeted refresh operation is performed. In some embodiments of the disclosure, the addresses for the victim rows to be refreshed by the targeted refresh may be provided based on other information.

In some embodiments of the disclosure, the method 1600 may be included in or is in addition to the method 400. For example, the method 1600 may be performed before box 430. As a result, the deficit counts may already be modified and the aggressor address added to the aggressor queue by the method 1600 when determining whether or not to perform a background refresh operation at box 430.

In some embodiments, the method 400 may include receiving a refresh command which specifies the bank. When a refresh command is received, the step of box 432 may still be performed, and if a refresh is not needed then the refresh operation may be skipped. If a refresh operation is needed, such as for a word line corresponding to a refresh address provided by a refresh address counter or for victim word lines corresponding to refresh addresses provided by a targeted refresh address generator 344, then the method may include performing one or more refresh operations responsive to receiving the refresh command. Refresh operations performed in this way may be performed without accessing a word line.

In some embodiments, box 420 may be modified, and the memory device may automatically have an opportunity for a background refresh operation. Instead, of determining if there is a refresh opportunity, box 420 may describe determining a timing of the access operation based on a comparison of a section select bit of the address received in box 410 to a previous section select bit (e.g., stored in a latch such as 254 of FIG. 2). For example, if the section selection bit matches the previous section selection bit a first timing may be used (e.g., tRP_S) while if the section selection bit does not match, a section timing may be used (e.g., tRP_L). In such embodiments, the background refresh operation may be performed in a section which is not the portion where the access operation is being performed.

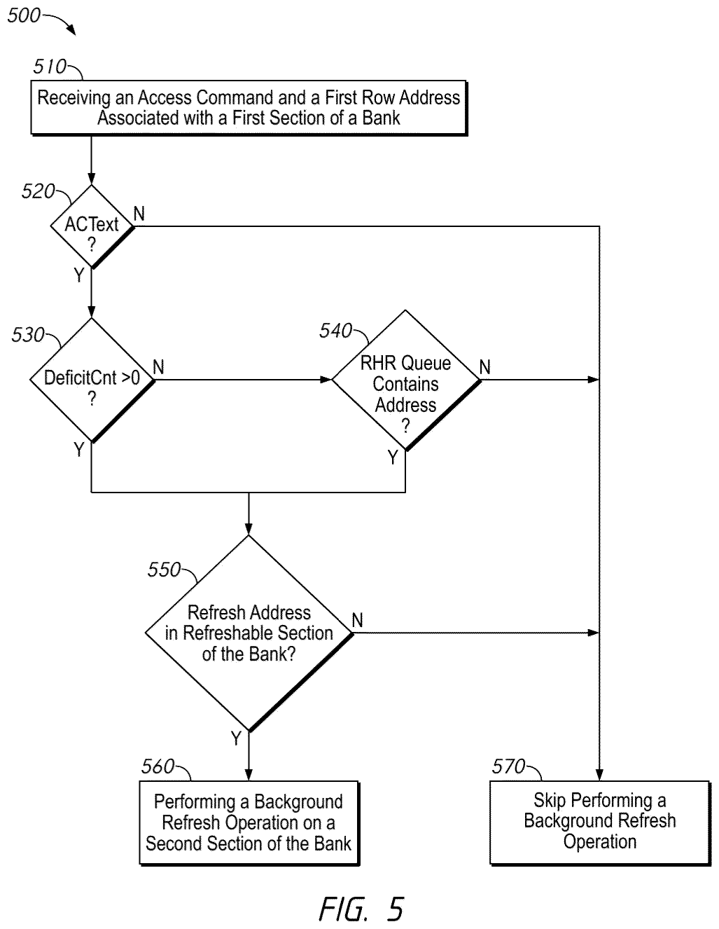

FIG. 5 is a flow chart of a method of determining whether or not to perform a background refresh operation according to some embodiments of the present disclosure. The method 500 may be implemented by one or more of the apparatuses or systems described herein. For example, the method 500 may be implemented by one or more of the memory devices described herein, such as the memory device 100 of FIG. 1, 220 of FIG. 2, 300 of FIG. 3, or combinations thereof. The method 500 may, in some embodiments, be an implementation of the method 400 of FIG. 4.

The method 500 begins with box 510, which describes receiving an access command and a first row address associated with a first section of a bank. Box 510 is followed by box 520, which describes determining if the access command specifies an extended timing window (e.g., ACText). For example, the method 500 may include determining if an extended activation bit of the activation command is active or not. If the command does not specify an extended timing window, the method 500 proceeds to box 570, which describes skipping performing a background refresh operation. If the access command does specify an extended timing window, the method 500 proceeds to box 530.

Box 530 describes determining if a first refresh deficit count (e.g., 134 of FIG. 1, 244/245 of FIG. 2, 332 of FIG. 3, or combinations thereof) is above zero. The refresh deficit count is non-zero, the method 500 proceeds to box 550. If the deficit count is zero, the method 500 optionally proceeds to box 540. Box 540 describes determining if the aggressor queue (e.g., 250 of FIG. 2, 324 of FIG. 3, or combinations thereof) contains an address. If it does not, the method 500 proceeds to box 570, skipping the background refresh operation. If there is at one address in the queue, the method 500 proceeds to box 550. In some embodiments, box 530 may include proceeding to box 550 even if the deficit count is zero. For example, box 530 may include determining if the deficit count is above zero, and if it is not, determining if a background refresh count is under a background refresh threshold. If the background refresh count is under the threshold, the method may proceed to box 550.

In some embodiments of the disclosure, the refresh deficit count is modified when a word line has been determined to be an aggressor word line. For example, as previously described, whenever a word line has been determined to be an aggressor word line, the refresh deficit count is increased so that at least one of the refresh operations performed to erase the refresh deficit may be allocated to a targeted refresh. In this manner, refresh operations for targeted refresh may be more efficiently managed with other refresh operations for the bank. Rather than proceeding to box 540 to determine if the aggressor queue contains an aggressor address, management of targeted refreshes is folded into the process of determining if the refresh deficit count is above zero at box 530, and then performing refresh operations, including stand-alone or background refreshes, to erase any refresh deficit as represented by the refresh deficit count.

Box 550 describes determining if the refresh address is in a refreshable section of the bank or not. The method 500 may include determining the refreshable section(s) based on the location of the first section. For example, the refreshable sections may be at least two sections away from the first section. The method 500 may include determining the refresh address based on a refresh address counter (e.g., 132 of FIG. 1, 242/243 of FIG. 2, 342/343 of FIG. 3, or combinations thereof) if the deficit counter is above zero, and determining the refresh address based on an aggressor address from the aggressor queue if the deficit counter is zero and there was an address in the queue. The method 500 may include comparing the section which includes the word line associated with the refresh address to the refreshable sections. If the deficit counter is above zero, then both refresh addresses from both refresh address counters may be checked. If both refresh addresses are in refreshable sections, then the refresh address counter with the lower value is chosen. If no address is refreshable, then the method 500 proceeds to box 570, skipping the background refresh operation. If the refresh address is refreshable, then the method 500 proceeds to box 560. Box 560 describes performing a background refresh operation on a second section of the bank (e.g., box 440 of FIG. 4).

FIG. 6 is a table of an example of how an extended activation command may be transmitted to the memory according to some embodiments of the present disclosure. The table 600 represents an example of how command/address or CA terminals of the memory may be used to receive an ACT command, and how that may be used to distinguish between a normal activate command ACT and an extended activate command ACText. The ACT command of FIG. 6 may be received as part of an access command. The table 600 of FIG. 6 may, in some embodiments, represent the operation of a memory device such as 100 of FIG. 1, 220 of FIG. 2, 300 of FIG. 3 or combinations thereof. The table 600 may represent signals sent to the memory by a controller such as 210 of FIG. 2 in some embodiments. In some embodiments, if the activation command is an extended activate command ACText, then the memory may interpret that as an opportunity for a background refresh operation, for example as described in block 420 of FIG. 4, block 520 of FIG. 5, or combinations thereof.

The table 600 shows the function of the command, activating a word line, as well as the abbreviation ACT. Also shown is the state of the chip select pin CS_n, where n is the designation for the memory device. The example of table 6 shows 14 CA terminals, here labeled CA0 to CA13. Each of those terminals may carry a one bit signal, which may have a first meaning when the CS_n pin has a logical low, and a second meaning when CS_n has a logical high. By transmitting information across the fourteen CA pins at a first time when CS_n is at a logical low and then at a second time when CS_n is at a logical high, up to 28 bits of information may be transmit as part of an activation command packet. In this example, the command packet indicates an activate command, for example as part of a read or write operation, a row address, and a bank address. While a certain number of bits and certain uses for those bits are shown in FIG. 6, other arrangements of information may be used in other example embodiments.

As part of the activation packet, when the CS_n pin is at a low logical level, the first two pins CA0 and CA1 are also kept at a low logical level. This may indicate that the command is an activate command. While CS_n is low, pins CA2 to CA5 carry the first four bits of the row address R0 to R3. Pins CA5 to CA10 carry the bank address bits BA0 and BA1 and bank group address BG0 to BG2. These five bits can be decoded (by the address decoder) into the bank address BADD. Pins CA11 to CA13 carry chip identification bits CID0 to CID2 respectively. When CS_n is low, the pin CA13 may be used to indicate if the activation command is an extended activation command ACText or not. For example, as part of an activation packet, when CS_n is low and CA13 is a logical low, the activation command may be a normal activation command. As part of an activation packet, when CS_n is low and CA13 is a logical high, the activation command may be an extended activation command ACText.

As part of the activation packet, when CS_n is a logical high, then CA pins CA0 to CA12 represent row address bits R4 to R16 respectively. The pin CA13 represents a fourth CID bit CID3 or an eighteenth row address bit R17 depending on the configuration.

By setting aside one of the CA pins, in this case CA13 when CS_n is low, to designate whether the activate command is a normal or extended activate, the controller may signal to the memory device that the access operation performed in response to the activate command should have an extended timing window.

Other pins and signals may be used in other example embodiments. For example, other pins, such as CA11 or CA12 may be used, or other states of CS_n, such as CA13 when CS_n is high instead of low. In some embodiments, a different command packet may be used to indicate an extended access operation. For example, instead of using the activation command ACT to indicate an extended operation as ACText, the pre-charge command may be used to mark that the next access operation is extended. For example, if a command Pre is received, then the next activation may have a normal (or short) time window such as tRP_S. If the extended pre-charge command Preext is received at the end of an access operation, the next access operation will be extended such as tRP_L, and the memory may use the next access operation as a background refresh opportunity. Similar to the example of FIG. 6 where one of the CA pins was used to note the difference between ACT and ACText, in embodiments where Pre and Preext are used, a CA pin may be set aside in the Pre charge command packet to determine whether the pre-charge command is Pre or Preext.

FIG. 7 is a timing diagram of a background refresh operation according to some embodiments of the present disclosure. The timing diagram 700 of FIG. 7 represents an example access operation with an extended timing window. For example, the timing diagram 700 may represent signals received by, and generated in, a memory device such as 100 of FIG. 1, 220 of FIG. 2, 300 of FIG. 3, or combinations thereof. In the view of FIG. 7, commands are abstracted as pulses which are active when the signal is sent/received and inactive otherwise. However, each command may represent any number of bits in any pattern of sequential or parallel transmission, and any combination of active and inactive ones of those bits.

The timing diagram 700 includes a first trace 710 which represents commands received from a controller. For example, the first trace may represent commands generated by a controller such as 210 of FIG. 2 and transmitted to the memory over one or more CA terminals. The timing diagram 700 also includes a second trace 720 which represents internal commands used by a row decoder (e.g., 108 of FIG. 1, 360 of FIG. 3, or combinations thereof) to activate a first row responsive to the access command received in the first trace 710. The timing diagram 700 also includes a third traces 730 which represents internal commands used by the row decoder to activate a second row as part of a background refresh operation.

At an initial time t0, the device receives an extended activation command ACText as shown in the first trace. For example, the extended activation command may be received using the signaling pattern shown in the table 600 of FIG. 6. Responsive to this, at the initial time t0, a row activation command ACT is sent to the first row as part of an access operation as shown in the second trace 720. At a second time t1, the memory receives a pre-charge command PRE as shown in the first trace 710. The time between t0 and t1 may be a row access strobe time tRAS. In some embodiments, tRAS may be 16 ns, although other lengths of time may be used in other example embodiments. The controller may send a pre-charge command PRE the row access strobe time tRAS after sending an activation command, either ACT or ACText. Also at the second time t1, the PRAC value from the first word line is read out to the refresh control circuit where it is checked to see if the first word line is an aggressor or not. This operation on the PRAC value is noted by the notation CNT.

In the example operation of FIG. 7, based on receiving an extended activation command ACText, a refresh control circuit (e.g., 116 of FIG. 1, 240 of FIG. 2, 340 of FIG. 3, or combinations thereof) determines that a background refresh should be performed for example if there is a refresh deficit, an aggressor address in the queue, or combinations thereof. Accordingly, at the second time t1, as shown in the third trace 730, a row activation command ACT is sent to the second row as part of a background refresh operation. At a third time t2, which is after the second time t1, the PRAC value from the second word line is read out to the refresh control circuit for a CNT operation. The time between t1 and t2 may be about tRAS long since the delay between the first row being activated at to and the second row being activated at t1 is about tRAS long. Since the CNT operation takes less than tRAS amount of time, the refresh control circuit is finished performing the CNT operation on the PRAC value of the first word line before the PRAC value of the second word line is sent to the refresh control circuit. In this way, even though the refresh control circuit is shared, there is no conflict between the first and the second word line using it, since they are staggered in time. At a fourth time t3, the first word line receives a pre-charge command and the first word line is deactivated as shown in the second trace 720. At a fifth time t4, the second word line receives a pre-charge command and the second word line is deactivated as shown in the third trace 730.

The memory specification defines a pre-charge recovery time tRP which must elapse after a pre-charge command before the word line can be accessed again. Since the same word line may be accessed again, the time tRP must generally elapse before a next access operation may occur. The time tRP may be about 36 ns in some embodiments. When a background refresh is performed, there is a delay time between when the first word line is activated as part of the access operation and when the second word line is activated as part of the background refresh operation. Since their activation times are separated (e.g., at t0 and t1 respectively), and since there is a generally fixed timing between activation and pre-charge commands (e.g., tRAS), the time at which they receive their respective pre-charge commands (e.g., t3 and t4, respectively). Accordingly, the time tRP must be allowed to elapse after the pre-charge command is received by the second word line, which activates later, before a next activation command can be received to account for situations where the next access is in, or close to, the section where the background refresh was performed. This is why the extended activation command ACText is used to mark when a background refresh may be performed.

Referring to the first trace 710 which shows commands received from the controller or sent by the controller, the extended activation command is received at the initial time to and then tRAS later at t1, the pre-charge command PRE is received. The time tRP elapses at t4, which is when a next activation command could be received if the activation command at t0 was a regular activation command. Since the activation command received at t0 was an extended activation command ACText, an additional extension time tRPext is added. At the time t5, which is tRP plus tRPext after t1 when the pre-charge command was received, a next activation command is received. The time tRPext may, in some embodiments be about 16 ns. While tRPext and tRAS are the same length in this example, they do not have to be. Longer or shorter time periods for each of tRP, tRAS, and tRPext may be used in other example embodiments. The time tRP represents a short pre-charge recover tRP_S. The time tRP+tRPext (e.g., about 52 ns in this example) represents a long pre-charge recovery time tRP_L. The activation command received at t5 is a normal activation command ACT (instead of ACText). Accordingly, the next access operation would be performed over tRAS+tRP amount of time, and only an access operation, but not a background refresh operation would generally be performed.

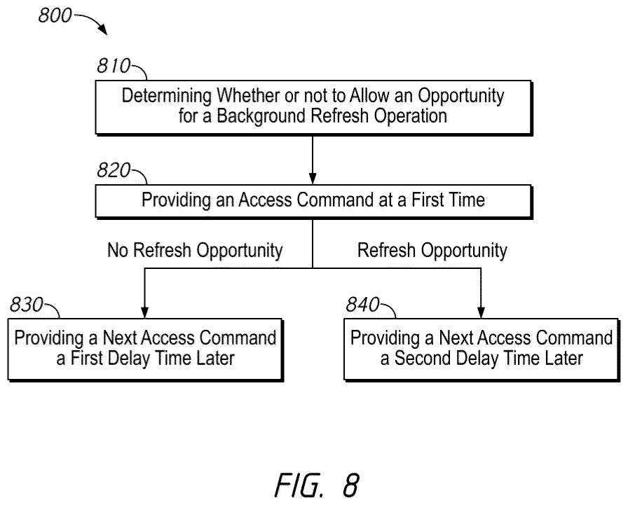

FIG. 8 is a flow chart of a method of sending access commands to a memory according to some embodiments of the present disclosure. The method 800 may be implemented by one or more of the apparatuses or systems described herein. For example, the method 800 may, in some embodiments, be performed by a controller, such as 210 of FIG. 2.

The method 800 may generally begin with block 810, which describes determining whether or not to allow an opportunity for a background refresh operation. For example, an access logic circuit, such as 216 of FIG. 2, may determine if there is time for an extended activation operation or not. The method 800 may include defaulting to providing an opportunity for a background refresh unless the controller is busy.

Block 810 is generally followed by block 820, which describes providing an access command at a first time. The access command may be a first type of access command, such as a regular access command, if block 810 determined not to allow an opportunity for a background refresh operation, or a second time of access command, such as an extended access command, if block 810 determined to allow an opportunity for a background refresh operation. For example, the method 800 may include providing an activation command packet with a bit in a first state if the controller is sending a regular access command and providing an activation command packet with the bit in a second state if the controller is sending an extended access command. For example, the controller may send the signals as described in the table 600 of FIG. 6.

Block 820 is followed by box 830 if the box 810 determine not to allow a refresh opportunity and is followed by box 840 if box 810 determined to allow a refresh opportunity. Box 830 describes providing a next access command a first delay time later. Box 840 describes providing the next access command a second delay time later. The second delay time is longer than the first delay time. For example, box 830 may include waiting a time which includes tRP_S (or tRP) after providing the access command before providing the next access command. Box 840 may include waiting a time which includes tRP_L (or tRP+tRPext) after providing the access command before providing the next access command. In some embodiments, the method 800 may include providing the access command, waiting a time tRAS plus either tRP_S or tRP_L before providing the next access command. The method 800 may include providing a pre-charge command the time tRAS after providing the access command. Examples of these times may be seen in FIG. 7.

A memory device may receive the access command. If the access command allows for a background refresh, then the memory may determine whether or not to perform a background refresh operation. For example, the command provided in box 820 of FIG. 8 may be the command received in box 410 of FIG. 4, box 510 of FIG. 5, or combinations thereof in some embodiments.

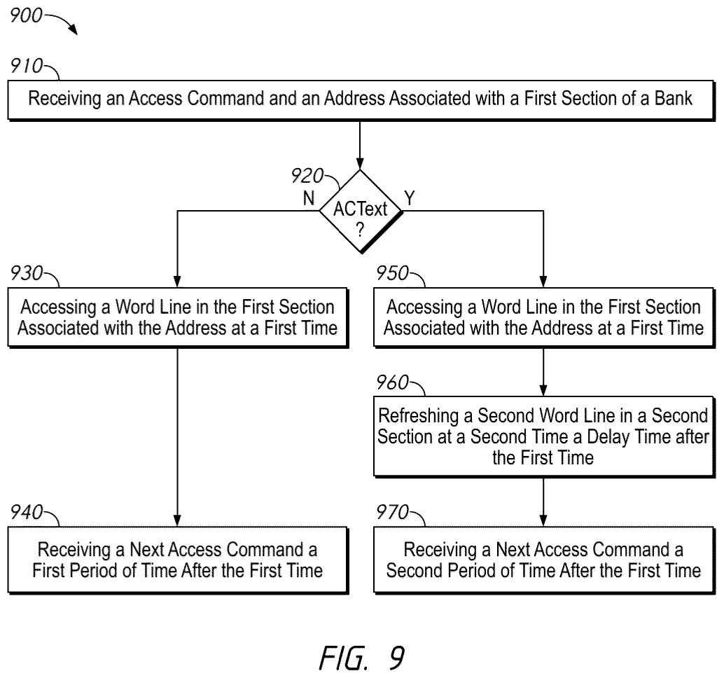

FIG. 9 is a flow chart of a method of performing background refresh operations according to some embodiments of the present disclosure. The method 900 may be implemented by one or more of the apparatuses and systems described herein. For example, the method 900 may be implemented by a memory device such as 100 of FIG. 1, 220 of FIG. 2, 300 of FIG. 3 or combinations thereof.

The method 900 may generally begin with box 910, which describes receiving an access command an address associated with a first section of a bank. The access command and address may be received along CA terminals, for example in the pattern shown in the example of the table 600 of FIG. 6. Box 910 is followed by box 920, which describes determining if the access command is an extended access command. Box 920 may be generally similar to the box 420 of FIG. 4, box 520 of FIG. 5, or combinations thereof. Box 920 may include determining if the access command is extended based on a state of a bit along one of the CA terminals, for example the state of CA13 when CS_n is a logical low as described in FIG. 6. If the access command is not extended, then box 920 is followed by boxes 930 and 940. If the access command is extended, then box 920 is followed by boxes 950-970.

If the access command is not extended, then box 920 is followed by box 930, which describes accessing a word line in the first section associated with the address at a first time. The method 900 may include generating an internal activation command or signal at the first time and activating the word line at the first time. Box 930 is followed by box 940, which describes receiving a next access command a first period of time after the first time. The first period of time may be a time tRAS plus a first recovery time tRP_S (or tRP). Box 930 may include generating an internal pre-charge command and deactivating the accessed word line after the time tRAS. The first time may be the time between t0 and t4 of FIG. 7 in some example embodiments.

If the access command is extended, then box 920 is followed by box 950, which describes accessing the word line in the first section associated with the address at the first time. The box 950 may be generally similar to the box 930. For the sake of brevity, the details already described with respect to box 930 will not be repeated with respect to box 950. Box 950 is followed by box 960, which describes refreshing a second word line in a second section at a second time which is a delay time after the first time. The refreshing of box 960 may include generating an internal activation command or signal at the second time and activating the second word line responsive to the internal activation command. The time at which the first word line is active while it is being accessed may overlap with the time the second word line is active while it is being refreshed. For example, the method 900 may include generating an internal pre-charge command at a third time and deactivating the first word line responsive to the pre-charge command and generating a second internal pre-charge command at a fourth time and deactivating the second word line responsive to the second internal pre-charge command. The third time is after the second time but before the fourth time.

Box 960 is followed by box 970, which describes receiving a next access command a second period of time after the first time. The second period of time may be a time tRAS plus a second recovery time tRP_L (or tRP+tRPext). In other words, the second period of time may be a pre-charge extension time tRPext longer than the first period of time.

In some embodiments, the method 900 may include determining whether or not to perform the refresh operation. For example the method 900 may include the steps of box 430 of FIG. 4, 530-550 of FIG. 5, or combinations thereof. If the memory decides to skip the refresh operation, then box 960 is not performed, and box 970 follows box 950.

FIGS. 10-11 describe an example embodiment where the row address is used to determine if a background refresh may be performed. The row address may be used instead of, or in addition to using an extended access command, such as was discussed FIG. 6. In the embodiment of FIGS. 10-11, some background refresh operations may be performed without extending the time between access operations. For example, a background refresh may be performed even when the next access command is received tRP_S later.

FIG. 10 is a timing diagram of background refresh operations according to some embodiments of the present disclosure. The timing diagram 1000 may represent signals received by, and generated in, a memory device such as 100 of FIG. 1, 220 of FIG. 2, 300 of FIG. 3, or combinations thereof. The timing diagram 1000 may be generally similar to the timing diagram 700 of FIG. 7, except that the timing diagram 1000 describes an embodiment wherein the controller uses a row address' section select bit to determine timing of access operations, and the memory does not rely on an extended activation command as was described in the embodiment of FIG. 7. For the sake of brevity, certain details and conventions already described with respect to FIG. 7 will not be repeated again with respect to FIG. 10.

FIG. 10 shows three traces, a first trace 1010 which represents commands from a controller received by the memory, a second trace 1020 which represents internal signals used as part of operations in a first portion (e.g., 270 of FIG. 2) of the memory bank, and a third trace 1030 which represents internal signals used as part of operations in a second portion (e.g., 280 of FIG. 2) of the memory bank.

In FIG. 10, the first trace 1010 also includes a state of a section select bit of the row address. FIG. 10 shows the most significant bit or MSB, but other bits of the row address may be used as the section select bit in other example embodiments. The state of the bit indicates if the address is associated with a row address in a first portion or a second portion of the memory array. The controller may determine a timing between access operations based, in part, on the address bit. The two portions may correspond to the portions associated with a first refresh address circuit (e.g., 242 of FIG. 2, 342 of FIG. 3, or combinations thereof) and a second refresh address circuit (e.g., 243 of FIG. 2, 343 of FIG. 3, or combinations thereof) respectively.

When the address bit indicates that a first portion is being accessed, a background refresh may be performed in the second section. If a next access operation is performed on the same portion and the next address bit has the same state, then the background refresh will also be performed on a same portion as the previous background refresh operation. For example if the first portion is accessed twice in a row, then for both access operations a background refresh operation is performed in the second portion. Because of this, during the second access operation there is a reduced risk of the second access interfering with the pre-charge from the refresh operation which happened during the first access operation. This may allow two consecutive access operations in the same portion, with the same value of the address bit, to be separated by tRP_S. When the next access operation is in the other portion, and the next address has a different state of the bit, then the access operations are separated by tRP_L. The access logic of the controller (e.g., 216 of FIG. 2) may track the section select bits to determine the timing at which to provide access operations.

FIG. 10 shows a sequence of example operations. At an initial time to, an access operation is received with an address bit which specifies a first portion, here noted as MSB=0. Accordingly at t0, an internal activation command is generated for the first portion for an access operation as shown in the second trace 1020. At a second time tRAS later, an internal activation command is generated for the second portion as part of a background refresh operation as shown in the third trace 1030. At a third time t2, which is tRP_S after the second time t1, a next activation command is received as seen in the first trace 1010. Since the activation command received at t2 comes with an address which is associated with a same portion as the activation received at t0 (e.g., the MSBs match), the controller sends the second access command tRAS+tRP_S after t0.

Responsive to the second access command received at t2, the memory generates an internal activate signal for the first portion as part of the access operation, as shown in the second trace 1020. At the same time, the memory is generating a pre-charge signal for the second portion, as shown in the trace 1030, as part of the background refresh operation which was performed in the second portion. At a fourth time t3 which is tRAS after t2, the memory generates an internal activation signal for the second portion, as shown in the third trace 1030.

At a fifth time t4, the memory receives the next activation command after the command received at t2. The command received at t4 has a different state of the address bit, and is associated with an access to the second portion of the array. For example the command at t4 has a row address with MSB=1. Since the access is in a different portion, the controller provides the access command at t4 an extended time after t3 compared to the time between t1 and t2. For example, the time between t2 and t4 may be tRAS+tRP_L, where tRP_L is tRP_S plus a delay time tRPext.

As may be noted, the embodiment of FIG. 10 differs from the embodiment of FIGS. 7-9, in that it is not necessary for the memory to receive an extended activation command in order for the memory to perform a background refresh operation. Instead, the row address is used by the controller to determine a timing of the access operations, and each access operation is background refresh opportunity.

FIG. 11 is a flow chart of a method of providing access commands with different timing based on an address according to some embodiments of the present disclosure. The method 1100 of FIG. 11 may, in some embodiments, be implemented by one or more of the apparatuses and systems described herein. For example, the method 1100 may be implemented by the controller 210 of FIG. 2 in some embodiments. The method 1100 may reflect the process the controller uses to send commands, such as the commands shown in the trace 1010 of FIG. 10.

FIG. 11 begins with box 1110, which describes providing an access command a first address at a first time. The first address is associated with a first portion of a memory array. Box 1110 is generally followed by box 1120. Box 1120 describes determining a second address for a next access command. Box 1120 may generally be followed by box 1130. Box 1130 describes determining if the second address is in the same portion of the memory bank as the first address. For example, the method may include comparing the state of one or more bits of the addresses. The bits specify whether the address is associated with the first or the second portion. For example, the method may include comparing a most significant bit of the first address to a most significant bit of the second address.

If the addresses are associated with the same portion, box 1130 is followed by box 1140 which describes providing the next access command and the second address a first period of time after the first time. If the addresses are associated with different portions, box 1130 is followed by box 1150, which describes providing the next access command and the second address a second period of time after the first time. The second period of time is longer than the first period of time. An access logic circuit of the controller (e.g., 216 of FIG. 2) may compare the addresses and determine when to provide the next access command.

FIG. 12 is a flow chart of a method of maintaining a refresh deficit count and determining a count value to write to a mode register according to some embodiments of the present disclosure. The method 1200 may be implemented by one or more of the memory devices described herein, such as the memory device 100 of FIG. 1, 220 of FIG. 2, 300 of FIG. 3, or combinations thereof.

The method 1200 begins with box 1210, which describes changing a first count value based on a number of elapsed refresh intervals. The refresh intervals are determined based on a number of refresh operations which need to be performed to refresh each of the word lines of the bank and an amount of time that the memory cells of a word line can go between refresh operations. Accordingly, the refresh interval tREFI may represent an average time between refresh operations required to refresh every word line in the specified window of time, if the refresh operations were performed at an average rate. The refresh interval tREFI may thus represent an expected time between refresh operations and the first count value may thus represent an expected number of refresh operations. For example, the first count value may represent a number of refreshes that should have been performed so far in the current refresh period. If the performed number of refresh operations does not match the expected number of refresh operations, a refresh deficit may exist. The elapsed refresh intervals (e.g., the first count value) may be tracked by a refresh period counter (e.g., 140 of FIGS. 1 and/or 222 of FIG. 2). The terms “expected refresh count value” and “refresh interval count” may be used interchangeably.

In some embodiments, box 1210 may include updating the first count value based on a signal from an oscillator circuit, such as the oscillator 142 of FIG. 1. For example, box 1210 may include incrementing the first count value on rising edges of the oscillator signal. In some embodiments, the method 1200 may include adjusting a period of the oscillator circuit based on one or more settings of the memory, current conditions of the memory, or combinations thereof. For example, box 1210 may include adjusting a period of the oscillator signal based on a refresh multiplier mode register, and setting the refresh multiplier mode register based, in part, on a measured temperature of the memory device.

The method 1200 also includes box 1220. Box 1220 describes changing at least one count value based on how many refresh operations have been performed on a bank. For example, the box 1220 may include box 1222 which describes changing a second count value based on how many refresh operations have been performed on a first portion of a bank (e.g., 270 of FIG. 2) and box 1225 which describes changing a third count value based on how many refresh operations have been performed on a second portion of the bank (e.g., 280 of FIG. 2). Other numbers of counters and other numbers of portions may be used in other example embodiments.

In an example implementation, the second count value may represent a value tracked by a first refresh address counter (e.g., 132 of FIG. 1, 242 of FIG. 2, and/or 342 of FIG. 3) associated with a first portion (e.g., 270 of FIG. 2) of a bank (e.g., 260 of FIG. 2 and/or 370 of FIG. 3), such as a first half of the bank.

Box 1225 describes changing a third count value based on how many refresh operations have been performed on a second portion of a bank. The third count value may represent a value tracked by a second refresh address counter (e.g., 132 of FIG. 1, 243 of FIG. 2, and/or 343 of FIG. 3) associated with a second portion (e.g., 280 of FIG. 2) of the bank, such as a second half of the bank. For example, method 1200 may be implemented on a memory device (e.g., 100 of FIG. 1, 220 of FIG. 2, and/or 300 of FIG. 3) that includes multiple refresh address counters (e.g., 132 of FIG. 1, 242/243 of FIG. 2, and/or 342/343 of FIG. 3) associated with each bank.

In some embodiments, only a single refresh count value may be used. For example, the method 1200 may be implemented on a memory device (e.g., 100 of FIG. 1, 220 of FIG. 2, and/or 300 of FIG. 3) that includes one refresh address counter (e.g., 132 of FIG. 1, 242/243 of FIG. 2, and/or 342/343 of FIG. 3) associated with each bank (e.g., 260 of FIGS. 2 and/or 370 of FIG. 3). For example, the box 1220 may include changing a second count value based on how many refresh operations have been performed on the bank.

Boxes 1210 and 1220 may generally be performed in parallel. The box 1210 describes a counter which is changed as a function of time, while the box 1220 describes counters which are changed as a function of performed refresh operations. Both boxes change count values which are used by box 1230. In some embodiments, box 1230 may be performed whenever either of box 1210 or box 1220 is performed. In some embodiments, box 1230 may be performed periodically. In some embodiments, a combination of criteria may be used to determine when box 1230 is performed, such as when the boxes 1210 or 1220 are performed and periodically.

Box 1230 describes determining a refresh deficit count based on a difference between the at least one count value and the first count value (e.g., tREFIcnt). In some embodiments, when the at least one count value is a single count value which represents refreshes across the whole bank, then box 1230 includes determining the refresh deficit count based on the difference between the count of refresh operations and the number of expected refresh operations. In embodiments where the at least one count value includes multiple count values, such as embodiments where boxes 1222 and 1225 are performed, box 1230 includes determining the refresh deficit count based on the first count value and a minimum count value of the second and the third count values. The minimum count value is determined by comparing the values of the refresh address counters, for example with a comparator circuit (e.g., 246 of FIGS. 2 and/or 334 of FIG. 3).

The method 1200 includes setting the refresh deficit count to 0 if the bank has performed more refresh operations than it was expected to, in other words the bank is ahead of schedule, or if the bank is right on schedule. For example, the value of the refresh deficit count (e.g., 134 of FIG. 1, 244 of FIG. 2, and/or 332 of FIG. 3) is set to 0 if the number of performed refresh operations (e.g., the second count value) is equal to or greater than the number of expected refresh operations (e.g., the first count value). Otherwise, if the bank is behind schedule, meaning the bank has not performed as many refresh operations as it was expected to in a given period, there is a refresh deficit. The method includes setting the value of the refresh deficit is set to the difference between the expected (e.g., the first count value) and the performed (e.g., the minimum of the second count value and the third count value) refresh operations if there are more expected than performed refresh operations. In other words, if the refresh address count value is less than the expected refresh count value (or the elapsed refresh interval count, e.g., tREFI), the refresh deficit counter is set to the difference between the refresh address count value and the expected refresh count value (or the elapsed refresh interval count, e.g., tREFI), otherwise the refresh deficit counter is set to 0.

In some embodiments, the method may include adjusting the first count value, the second count value, the third count value, or combinations thereof based on the number of the at least one count value used to track refresh operations. For example, the first count value may track expected refresh operations across the entire bank, while the second and third count values each count refresh operations across half the bank. Accordingly, an adjustment may be needed to determine the refresh deficit. For example, the box 1230 may include determining a minimum count value by comparing the values of the refresh address counters to each other and choosing the lowest value, for example with a comparator circuit (e.g., 246 of FIGS. 2 and/or 334 of FIG. 3). The refresh deficit count is then based on the difference between the minimum count value and the expected refresh count value (or the refresh interval count, e.g., tREFI) divided by the number of refresh address counters. The refresh interval count (e.g., tREFI) is divided by the number of refresh address counters because the refresh interval count applies to the entire bank and each refresh address counter is associated with a portion of the bank. In some embodiments, the minimum count value or the individual refresh address count values may be multiplied by the number of refresh address counters instead of dividing the refresh interval count. If the minimum count value is less than the expected refresh count value (or the refresh interval count) divided by the number of refresh address counters, the refresh deficit counter is set to the difference between the minimum count value and the refresh interval count (or the expected refresh count) divided by the number of refresh address counters, otherwise the refresh deficit counter is set to 0.

For example, method 1200 may be implemented on a memory device (e.g., 100 of FIG. 1, 220 of FIG. 2, and/or 300 of FIG. 3) that includes two refresh address counters (e.g., 132 of FIG. 1, 242/243 of FIG. 2, and/or 342/343 of FIG. 3) each associated with half of the bank. Box 1230 may include determining a minimum count value by comparing the values of the second count value (e.g., a first refresh address counter associated with a first half of the bank) to the third count value (e.g., a second refresh address counter associated with a second half of the bank) and choosing the lower of the two values, for example with a comparator circuit (e.g., 246 of FIGS. 2 and/or 334 of FIG. 3). The refresh deficit count is then based on the difference between the minimum count value and the first count value (e.g., the refresh interval count) divided by 2 (e.g., the number of refresh address counters). If the minimum count value is less than the first count value divided by 2, the refresh deficit counter is set to the difference between the minimum count value and the first count value divided by 2, otherwise the refresh deficit counter is set to 0. Once the refresh deficit count is determined, the method 1200 proceeds to box 1240.

Box 1240 describes writing the refresh deficit count to a mode register (e.g., 130 of FIG. 1, 230 of FIG. 2, and/or 314 of FIG. 3). The mode register (e.g., 130 of FIG. 1, 230 of FIG. 2, and/or 314 of FIG. 3) may include the storage of at least one refresh deficit count (e.g., 232/233 of FIGS. 2 and/or 316 of FIG. 3). The mode register may include a refresh deficit count for each bank of memory and each refresh deficit count may consist of multiple bits. For example, each refresh deficit count may consist of 2, 4, or any number of bits. The memory device (e.g., 100 of FIG. 1, 220 of FIG. 2, and/or 300 of FIG. 3) may write the refresh deficit count to the mode register continuously or periodically based on a timing protocol. In some embodiments, the box 1240 may be performed at certain times determined based on the count of refresh intervals. For example, when the first count value has certain values (e.g., multiples of four) the box 1240 is performed.

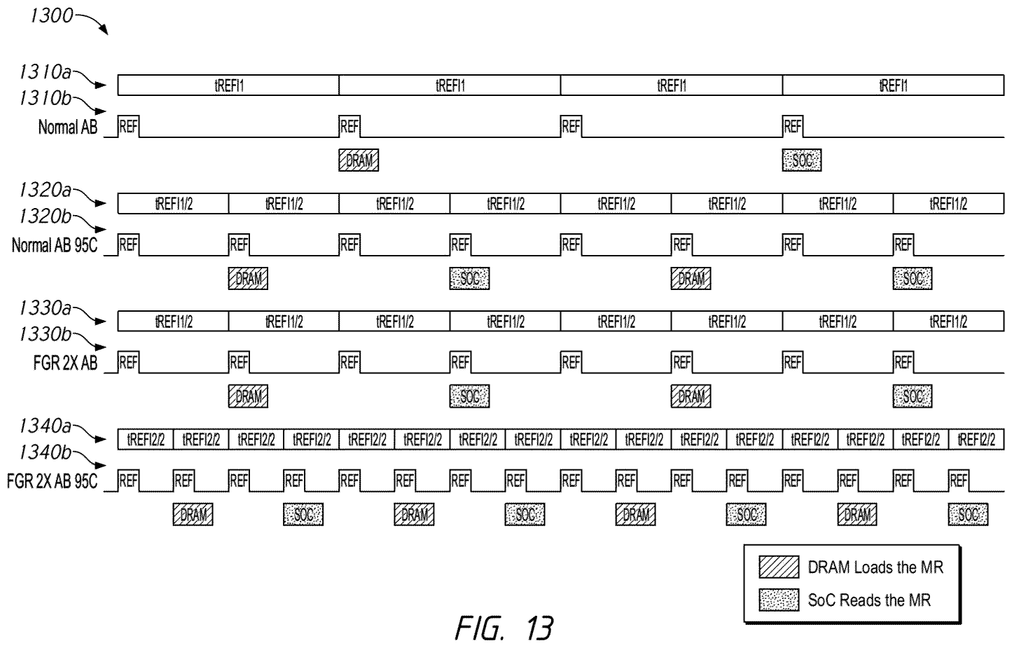

FIG. 13 is a timing diagram of protocols to coordinate mode register access between a memory device and a controller according to some embodiments of the present disclosure. The timing protocols of diagram 1300 may be implemented by system 200 of FIG. 2, the controller 210 of FIG. 2, one or more of the memory devices described herein, or combinations thereof. For example the timing protocols may be implemented by the controller 210 of FIG. 2, the memory device 100 of FIG. 1, 220 of FIG. 2, 300 of FIG. 3, or combinations thereof. The timing protocols 1200 of FIG. 12 may, in some embodiments, represent a timing at which box 1240 of FIG. 12 is performed.

In some embodiments, deficit counts are stored in a location, such as in a mode register (e.g., 130 of FIG. 1, 230 of FIG. 2, and/or 314 of FIG. 3) which is accessible both by the memory device (e.g., 100 of FIG. 1, 220 of FIG. 2, 300 of FIG. 3) and the controller (e.g., 210 of FIG. 2). For example, the refresh deficit count (e.g., 232/233 of FIGS. 2 and/or 316 of FIG. 3) may be written to the mode register by the memory device. The same mode register may be read by the controller (e.g., with an MRR operation) so that the controller can determine if refresh commands should be issued. So as not to interfere with each other, the memory device and the controller may perform their respective operations (e.g., reading from and/or writing to the mode register) according to coordinated timing protocols. In that way, the memory writes information to the mode register at a time when the controller is not reading the information from the mode register and vice versa. The read operations of the controller may be performed by a mode register access logic circuit (e.g., 218 of FIG. 2) of the controller. For example, the mode register access logic circuit (e.g., 218 of FIG. 2) may issue a mode register read (MRR) command to the memory device to perform a read operation. The write operations of the memory device may be performed by a mode register access logic circuit (e.g., 338 of FIG. 3) of the memory device.

In some embodiments, the refresh interval may be used to coordinate the timing between the memory and the controller accessing the mode register. For example, the controller and memory may each keep a count of elapsed refresh intervals using a controller refresh interval counter circuit (e.g., 212 of FIG. 2) and memory refresh interval counter circuit (e.g., 140 of FIG. 1, 222 of FIG. 2, 312 of FIG. 3, or combinations thereof) respectively. The two refresh interval counter circuits may each keep a count of the refresh intervals and may be synchronized to each other with an initial signal at an initial time. The synchronization may involve setting values of the refresh interval counter circuits to a same value at an initial time. For example, after a power up or reset operation, the controller may provide a refresh command to the memory 220 and responsive to that both the controller and memory refresh counters may reset to an initial value. Since the two counters should count at generally the same rate, and since the two counters should be initialized to a same value at the initial time, the two counters may generally be expected to closely match. In some embodiments, the two counters may be resynchronized. For example, the two refresh interval counters may be periodically resynchronized to a same value.

The controller and memory device may access the mode register, to read from it or write to it respectively, at a same period, however the two devices may be offset from each other in time. The period may be based on a specification of the memory. For example, the specification may allow up to Y refresh intervals elapse without a refresh operation. The value Y may be based on how many refresh operations can be performed responsive to a refresh command in order to catch up to or even out the missed refresh operations. FIG. 13 shows an example embodiment where the value of Y is four, however more or fewer refresh intervals may be used as the period in other example embodiments. In the example of FIG. 13, the controller may perform a mode register read on every fourth refresh interval and the memory device may write to the mode register on every fourth refresh interval, however the two devices may be offset from each other by two refresh intervals.

Accordingly, for example, the controller may read on refresh intervals 3, 7, 11, etc. while the memory may write to the mode register on intervals 1, 5, 9, etc.

The refresh interval length may change based on a current refresh mode. For example, the refresh mode may be normal refresh mode or fine granularity refresh (FGR) mode. FGR mode may require refresh commands to be provided more often and thus, with a shorter refresh interval, such as a refresh interval half as long as a refresh interval in normal refresh mode. The refresh mode may also be based on the operating temperature of the system (e.g., 200 of FIG. 2). For example, a memory device operating at a higher temperature (e.g., at or above 95 degrees Celsius) may require refresh operations more often than, for example twice as often as, a memory device operating at a lower temperature. The aforementioned refresh modes apply to all bank refresh (REFab) operations. The timing diagram 1300 shows a variety of different refresh modes, as well as how those modes change the rate at which the controller and memory access the mode register. The signal REF is used to indicate an elapsed refresh interval in FIG. 13, with the notation tREFI indicating a ‘default’ refresh interval length. Accordingly, the actual timing of the refresh intervals REF may be expressed in terms of the default tREFI.

Turning to diagram 1300, lines 1310a and 1310b depict the timing of the operations of the mode register access logic circuits (e.g., 218 of FIG. 2 and 338 of FIG. 3) during an all bank refresh operation in normal mode. Line 1310a shows the refresh interval timing tREFI1 and line 1310b shows when the operations of the mode register access logic circuits (e.g., 218 of FIG. 2 and 338 of FIG. 3) occur. A write operation is performed at the beginning of the second refresh interval (shown as DRAM in FIG. 13) and a read operation is performed at the beginning of the fourth refresh interval (shown as SoC in FIG. 13). The timing of the operations repeats until the refresh period is complete and the refresh interval count (e.g., tREFIcnt) maintained by a memory device refresh period counter (e.g., 140 of FIG. 1, 222 of FIG. 2, and/or 312 of FIG. 3) and a controller refresh period circuit (e.g., 212 of FIG. 2) resets. For example, the write operations occur every four refresh intervals starting in the second refresh interval and the read operations occur every four refresh interval starting in the fourth refresh interval until the end of the refresh period.

Lines 1320a and 1320b depict the timing of the mode register access logic circuits (e.g., 218 of FIG. 2 and 338 of FIG. 3) during an all bank refresh operation in normal mode at a high temperature. In some embodiments, the refresh intervals may occur twice as often as the refresh intervals of a normal refresh operation at a lower temperature. Line 1320a shows the refresh interval timing tREFI1/2 and line 1320b shows when the operations of the mode register access logic circuits (e.g., 218 of FIG. 2 and 338 of FIG. 3) occur. A write operation is performed at the beginning of the second refresh interval (shown as DRAM in FIG. 13) and a read operation is performed at the beginning of the fourth refresh interval (shown as SoC in FIG. 13). The timing of the operations repeats until the refresh period is complete. For example, the write operations occur every four refresh intervals starting in the second refresh interval and the read operations occur every four refresh interval starting in the fourth refresh interval until the end of the refresh period. In some embodiments, the read and write operations occur twice as often during an all bank refresh in normal high temperature mode than the operations occur during an all bank refresh in normal mode for lower temperatures over the same amount of time. For example, four operations (two read and two write) shown on line 1320b of FIG. 13 occur over the same amount of time as the two operations (one read and one write) shown on line 1310b of FIG. 13.

Lines 1330a and 1330b depict the timing of the mode register access logic circuits (e.g., 218 of FIG. 2 and 338 of FIG. 3) during an all bank refresh operation in FGR mode. In some embodiments, the refresh intervals in FGR mode may occur twice as often as the refresh intervals in normal mode. Line 1330a shows the refresh interval timing tREFI2 and line 1330b shows when the operations of the mode register access logic circuits (e.g., 218 of FIG. 2 and 338 of FIG. 3) occur. A write operation is performed at the beginning of the second refresh interval (shown as DRAM in FIG. 13) and a read operation is performed at the beginning of the fourth refresh interval (shown as SoC in FIG. 13). The timing of the operations repeats until the refresh period is complete. For example, the write operations occur every four refresh intervals starting in the second refresh interval and the read operations occur every four refresh interval starting in the fourth refresh interval until the end of the refresh period. In some embodiments, the read and write operations occur twice as often during an all bank refresh in FGR mode than the operations occur during an all bank refresh in normal mode over the same amount of time. For example, four operations (two read and two write) shown on line 1330b of FIG. 13 occur over the same amount of time as the two operations (one read and one write) shown on line 1310b of FIG. 13.

Lines 1340a and 1340b depict the timing of the mode register access logic circuits (e.g., 218 of FIG. 2 and 338 of FIG. 3) during an all bank refresh operation in FGR mode at a high temperature. In some embodiments, the refresh intervals may occur twice as often as the refresh intervals of an FGR refresh operation at a lower temperature which may be four times as often as the refresh interval in a normal refresh operation at a lower temperature. Line 1340a shows the refresh interval timing tREFI2/2 and line 1340b shows when the operations of the mode register access logic circuits (e.g., 218 of FIG. 2 and 338 of FIG. 3) occur. A write operation is performed at the beginning of the second refresh interval (shown as DRAM in FIG. 13) and a read operation is performed at the beginning of the fourth refresh interval (shown as SoC in FIG. 13). The timing of the operations repeats until the refresh period is complete. For example, the write operations occur every four refresh intervals starting in the second refresh interval and the read operations occur every four refresh interval starting in the fourth refresh interval until the end of the refresh period. In some embodiments, the read and write operations occur four times as often during an all bank refresh in FGR high temperature mode than the operations occur during an all bank refresh in normal mode for lower temperatures over the same amount of time. For example, eight operations (four read and four write) shown on line 1340b of FIG. 13 occur over the same amount of time as the two operations (one read and one write) shown on line 1310b of FIG. 13.

In some embodiments, to indicate to the memory device (e.g., 100 of FIG. 1, 220 of FIG. 2, 300 of FIG. 3) a refresh mode change from a lower frequency refresh interval to a higher frequency, such as a change from normal refresh mode to FGR mode or a change from a lower temperature mode to a high temperature mode, the controller (e.g., 210 of FIG. 2) writes to the mode register (e.g., 130 of FIG. 1, 230 of FIG. 2, and/or 314 of FIG. 3). The result of the mode change may be the addition of an extra least significant bit (LSB) to the refresh interval counters of the controller (e.g., 212 of FIG. 2) and the memory device (e.g., 140 of FIGS. 1 and/or 222 of FIG. 2). In some embodiments, the added LSB may have a value of 1. Similarly, to indicate to the memory device a refresh mode change from a higher frequency refresh interval to a lower frequency (e.g., from FGR mode to normal mode), the controller writes to the mode register. The result of the mode change may be the subtraction of the extra LSB from the refresh interval counters of the controller (e.g., 212 of FIG. 2) and the memory device (e.g., 140 of FIGS. 1 and/or 222 of FIG. 2).

In some embodiments, the controller may issue refresh commands to mark changes between different refresh modes, which in turn may signal that the memory should adjust the refresh interval timing. For example, the controller may issue an all bank refresh operation each time the refresh mode changes from FGR mode to normal mode. In some embodiments, the controller may issue two all bank refresh operations each time the refresh mode changes from normal mode to FGR mode. In some embodiments, when the controller writes to the mode register to indicate a change in refresh mode, the controller may issue an all bank refresh for every refresh interval period that requires commands to be backed up. In some embodiments, before a memory device (e.g., 100 of FIG. 1, 220 of FIG. 2, 300 of FIG. 3) performs a self-refresh operation, the controller (e.g., 210 of FIG. 2) may issue enough all bank refreshes required to make all the refresh deficit counts (e.g., 232/232, 242/243 of FIGS. 2 and/or 316, 332 of FIG. 3) for every bank (e.g., 260 of FIGS. 2 and/or 370 of FIG. 3) equal, such as equal to 0. In some embodiments, a self-refresh operation by the memory device may also require that the refresh address counters (e.g., 132 of FIG. 1, 242/243 of FIG. 2, and/or 342/343 of FIG. 3) of each bank are equal to each other.

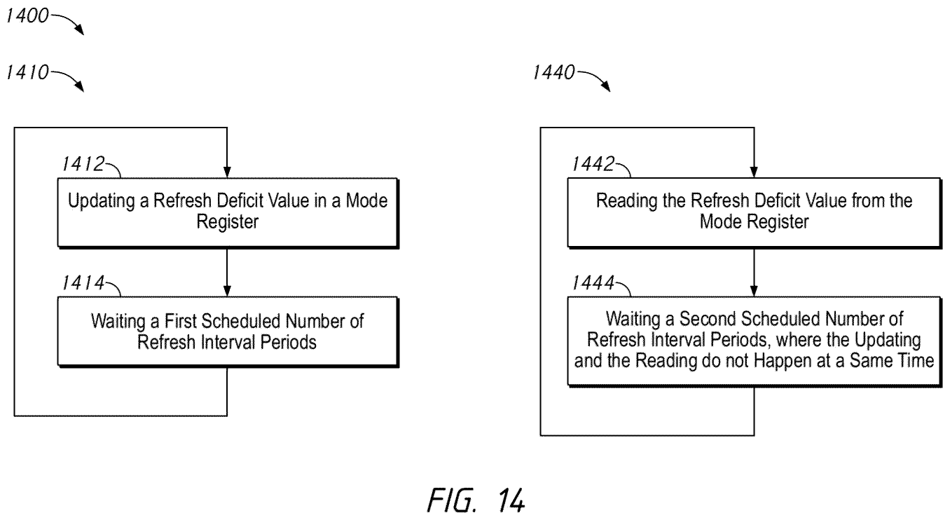

FIG. 14 is a flow chart of a method coordinating mode register access between a memory device and a controller according to some embodiments of the present disclosure. The method 1400 may be implemented by system 200 of FIG. 2 and/or one or more of the memory devices described herein, such as the memory device 100 of FIG. 1, 220 of FIG. 2, 300 of FIG. 3, or combinations thereof. The method 1400 may, in some embodiments, implement one or more parts of the method 1200 of FIG. 12, such as the box 1240.

The method 1400 is divided into related methods 1410 and 1440. Method 1410 describes a method of updating a refresh deficit value in a mode register. Method 1440 describes a method of reading the refresh deficit value from the mode register. The method 1410 may generally describe steps performed by a memory device, while the method 1440 may generally describe steps performed by a controller.

The method 1410 begins with box 1412, which describes updating a refresh deficit value in a mode register (e.g., 130 of FIG. 1, 230 of FIG. 2, and/or 314 of FIG. 3). The refresh deficit value may represent the value of a refresh deficit count (e.g., 232/233 of FIGS. 2 and/or 316 of FIG. 3) determined by the refresh control logic circuit (e.g., 330 of FIG. 3) and may be written by the mode register access logic circuit (e.g., 338 of FIG. 3) of the memory device. In some embodiments, the refresh deficit count may be determined based on boxes 1210-1230 of FIG. 12. Box 1412 may include overwriting the previous value in the mode register. In some embodiments, the update operation of the memory device may be an implementation of the write operations labelled “DRAM” in FIG. 13. After completion of the write operation, the method 1410 proceeds to box 1414.

Box 1414 describes waiting a first scheduled number of refresh interval periods (e.g., tREFI). In some embodiments, the memory device (e.g., 100 of FIG. 1, 220 of FIG. 2, and/or 300 of FIG. 3) may count a scheduled number of refresh interval periods based on the refresh period counter (e.g., 140 of FIG. 1, 222 of FIG. 2, and/or 312 of FIG. 3). For example, the mode register access logic circuit (e.g., 338 of FIG. 3) of the memory device may count the number of refresh interval periods, such as by monitoring the refresh period counter (e.g., 140 of FIG. 1, 222 of FIG. 2, and/or 312 of FIG. 3) until a scheduled number have passed since the write operation. The first scheduled number of refresh interval periods may be any number, such as 2, 4, or 6. In some embodiments, the refresh interval may be an implementation of the refresh intervals (e.g., tREFI) shown in FIG. 13. After the first scheduled number of refresh intervals have passed, the method 1410 may generally repeat block 1412. In this manner, the block 1412 may be repeated every first number of refresh interval periods.

In parallel to the memory performing method 1410, the controller performs method 1440. The method 1440 includes block 1442. Block 1442 describes reading the refresh deficit value from the mode register. For example, box 1442 may include issuing an MRR command to the memory device (e.g., 100 of FIG. 1, 220 of FIG. 2, and/or 300 of FIG. 3). The MRR command may specify the mode register which includes the refresh deficit value. In some embodiments, the mode register access logic circuit (e.g., 338 of FIG. 3) of the memory device may perform the read operation by accessing the refresh deficit count (e.g., 232/233 of FIGS. 2 and/or 316 of FIG. 3). In some embodiments, the read operation of the memory device may be an implementation of the read operations labelled “SoC” in FIG. 14. Box 1442 is followed by box 1444.

Box 1444 describes waiting a second scheduled number of refresh interval periods. In some embodiments, the second scheduled number of refresh interval periods is the same number of refresh interval periods as were waited after the write operation (e.g., the first number is the same as the second number). The second scheduled number of refresh interval periods may be any number, such as 2, 4, or 6. After the second scheduled number of refresh intervals have passed, the method 1440 returns to block 1442. In this manner, the controller may perform a mode register read operation every second scheduled number of refresh interval periods. The method 1400 includes performing the updating of block 1412 and the reading of block 1442 such that the updating and the reading do not occur at a same time. The updating and the reading operations may be staggered. For example, the updating operations will not conflict with the read operations, thus allowing the controller (e.g., 210 of FIG. 2) to read the mode register while not interfering with update operations by the memory device (e.g., 100 of FIG. 1, 220 of FIG. 2, and/or 300 of FIG. 3). This cadence of alternation read and write operations may continue until the end of the refresh period.

From the memory's perspective, the method 1400 may include updating the refresh deficit value in the mode register at a first time, waiting the first scheduled number of refresh interval periods, updating the refresh deficit value in the mode register at a second time, and providing the refresh deficit value responsive to a mode register read operation received at a third time, where the third time is between the first and the second times.

In some embodiments, the first and the second number of scheduled refresh interval periods may be the same, however the updating of box 1412 and the reading of box 1442 may be offset from each other. In some embodiments, the method 1400 may include synchronizing a refresh interval counter circuit (e.g., 212 of FIG. 2) on the controller and a refresh interval counter circuit (e.g., 140 of FIG. 1, 222 of FIG. 2, 312 of FIG. 3, or combinations thereof) on the memory to each other. In some embodiments, the method 1400 may include adjusting a duration refresh interval period on both the controller and memory based on a refresh setting, a condition of the memory such as temperature, or combinations thereof.

FIG. 15 is a flow chart of a method of aggregating refresh deficit counts from a plurality of banks to determine a refresh scheme according to some embodiments of the present disclosure. The method 1500 may be implemented by one or more of the apparatuses or systems described herein. For example, the method 1500 may be implemented by a controller, such as 210 of FIG. 2, a memory device, such as 100 of FIG. 1, 220 of FIG. 2, 300 of FIG. 3, or combinations thereof, or combinations thereof.

The method 1500 describes a process of using the refresh deficit counts for multiple banks to determine if a controller (e.g., 210 of FIG. 2) should issue refresh commands to the memory. If the refresh counts indicate a deficit, the controller may issue refresh commands to the memory and the memory may perform stand-alone refresh operations to minimize or eliminate the deficit. The refresh deficit counts may be used to determine how many refresh commands should be issued, what type of refresh commands to issue, or combinations thereof. For example, in some embodiments a number of refresh commands may be issued to perform a minimum number of refresh operations required to zero out the refresh deficit counters. This may be determined based on a maximum refresh deficit value, as that will indicate the bank which requires the most refresh operations to catch up to the expected number of refresh operations. In some embodiments, the types of refresh command may be selected such that the fewest possible banks receive refresh commands. For example, refresh commands may be selected which specify a set of banks which includes the banks which require refreshing, but which is the smallest total number of banks possible.

In some embodiments, the method 1500 may be implemented on a controller. The controller may read the deficit counts for multiple banks (e.g., from a mode register) and then use those counts to perform the method 1500 and determine which refresh commands, how many refresh commands, or combinations thereof, to issue. In some embodiments, the method 1500 may be primarily performed on the memory device. The memory may check the deficit count values for multiple banks and then use that information to determine how many refresh commands, what type of refresh commands, or combinations thereof, are required. The memory may write such information to a mode register, where the controller can read it. Based on the information read by the controller, the controller may then issue the appropriate types and numbers of refresh commands. FIG. 15 is generally described with respect to an example implementation where the controller performs the method 1500, however the memory may also perform analogous steps in other example embodiments.

The method 1500 begins with box 1510, which describes reading a plurality of refresh deficit count values associated with a plurality of banks in a mode register of a memory. The reading may be the method 1440 of FIG. 14 in some embodiments. The mode register (e.g., 130 of FIG. 1, 230 of FIG. 2, and/or 314 of FIG. 3) stores at least one refresh deficit count (e.g., 232/233 of FIGS. 2 and/or 316 of FIG. 3) for each bank (e.g., 260 of FIGS. 2 and/or 370 of FIG. 3) on the memory device. In some embodiments, the controller (e.g., 210 of FIG. 2) may send an MRR command to the memory device requesting all of the refresh deficit counts for all of the banks. In some embodiments, instead of or in addition to the refresh deficit counts being read out to the controller, the memory may collect the refresh deficit counts from multiple banks internally. After the refresh deficit counts have been read, the method 1500 will proceed to box 1520.

Box 1520 describes determining if any of the refresh deficit count values are greater than zero. In some embodiments, the controller (e.g., 210 of FIG. 2) may check each refresh deficit value to determine if any are greater than zero. For example, a refresh logic circuit (e.g., 214 of FIG. 2) of the controller may check each refresh deficit value. In some embodiments, the memory device (e.g., 100 of FIG. 1, 220 of FIG. 2, and/or 300 of FIG. 3) may check each refresh deficit value to determine if any are greater than zero. For example, a refresh control logic circuit (e.g., 248 of FIG. 2) of the memory device may check each refresh deficit value. The method 1500 may include determining what type of refresh command is needed based on the number of refresh deficit count values found to be greater than zero, which refresh deficit count values are greater than zero, or combinations thereof. In some embodiments, the refresh logic circuit (e.g., 214 of FIG. 2) of the controller may determine what type of refresh command to issue. In some embodiments, the refresh control logic circuit (e.g., 248 of FIG. 2) of the memory device may determine what type of refresh command it needs the controller to issue and write that information to the mode register for the controller to read.

If at least one of the refresh deficit counts is greater than zero, then box 1520 is followed by box 1530. If none of the refresh deficit counts is greater than zero, then the method 1500 may generally end with box 1520. Box 1530 describes determining if only one of the refresh deficit counts is greater than zero. If more than one of the refresh deficit count values is found to be greater than zero, the method 1500 proceeds to box 1540. If only one of the refresh deficit count values is found to be greater than zero, the method 1500 proceeds to box 1532.

Box 1532 describes providing a per bank refresh (REFpb) command to refresh the bank identified to have a refresh deficit count greater than zero. In some embodiments, the controller (e.g., 210 of FIG. 2) will issue the REFpb command to the memory device (e.g., 100 of FIG. 1, 220 of FIG. 2, and/or 300 of FIG. 3). The method 1500 may include issuing the REFpb command to the bank associated with the count which is greater than zero.

In some embodiments, even if multiple of the refresh deficit counts are greater than zero, the method 1500 may still proceed to box 1532. For example, the REFpb command may be issued based on the controller's (e.g., 210 of FIG. 2) evaluation of the refresh deficit count values as a whole. In an example implementation, if a small number (e.g., below a threshold number) of the refresh deficit count values are greater than zero, the controller may choose to refresh those banks individually by issuing REFpb commands to each of those banks. Accordingly, box 1532 may include providing a plurality of REFpb commands.

In some embodiments, the controller (e.g., 210 of FIG. 2) may issue a number of REFpb commands to the bank with the greater than zero refresh deficit count equal to the number of REFpb commands needed to clear the refresh deficit count (e.g., make the refresh deficit count value associated with the bank equal to zero). For example, if the refresh deficit count for a bank is 4, the controller will issue the corresponding number of REFpb commands required to clear the refresh deficit count for the associated bank. In some embodiments, the number of refresh commands needed to clear the refresh deficit count may be equal to the refresh deficit count value. In some embodiments, the number of refresh commands needed to clear the refresh deficit count may be different than the refresh deficit count value based on how many refresh operations are performed responsive to a refresh command.

Box 1540 describes determining if the plurality of banks with the refresh deficit count greater than zero have the same bank identification (ID). For example, the banks may be organized into bank groups, and each bank within that bank group may have a bank identification value. Accordingly, there may be a set of banks which all share a same bank identification value, each in a different bank group.

If the controller (e.g., 210 of FIG. 2) and/or the memory device (e.g., 100 of FIG. 1, 220 of FIG. 2, and/or 300 of FIG. 3) finds that multiple banks have a refresh deficit count value greater than zero, the controller and/or memory device (e.g., the refresh logic circuit 214 of FIG. 2 and/or the refresh control logic circuit 248 of FIG. 2) may evaluate each bank address associated with the refresh deficit count values greater than zero to determine whether they are associated with the same bank identification within a bank group, or in other words, have the same bank ID. If the refresh deficit counts are associated with banks with different bank IDs, the method 1500 will proceed to box 1544. If the refresh deficit counts are associated with banks with the same bank IDs, the method 1500 will proceed to box 1542.

Box 1542 describes providing a same bank refresh (REFsb) command. A REFsb command will refresh only the banks with the same bank ID across all of the bank groups. In some embodiments, the controller (e.g., 210 of FIG. 2) will issue the REFsb command to the memory device (e.g., 100 of FIG. 1, 220 of FIG. 2, and/or 300 of FIG. 3) and specify the bank ID which was associated with the plurality of non-zero refresh deficit counts. In some embodiments, the memory device will write a request for the REFsb command to the mode register.

In some embodiments, the memory device (e.g., 100 of FIG. 1, 220 of FIG. 2, and/or 300 of FIG. 3) may compare the refresh deficit count values (e.g., 232/233 of FIG. 2 and/or 316 of FIG. 3) of all of the banks sharing a bank ID, for example all banks in the same bank position of a bank group, to each other and find the maximum refresh deficit count value. The memory device may pass the maximum refresh deficit count value to the controller (e.g., 210 of FIG. 2) so that the controller may determine how many REFsb commands to provide accordingly. For example, the controller may issue enough REFsb commands to clear the highest refresh deficit count. For example, if the highest refresh deficit count value is 4, the controller may issue the number of REFsb commands needed to clear a refresh deficit count of 4 to the bank ID associated with the highest refresh deficit count. If the refresh deficit counts are associated with different bank IDs, the method 1500 will proceed to box 1544.

Box 1544 describes providing an all bank refresh (REFab) command. A REFab command will refresh all banks (e.g., 260 of FIGS. 2 and/or 370 of FIG. 3) of the memory device (e.g., 100 of FIG. 1, 220 of FIG. 2, and/or 300 of FIG. 3). In some embodiments, the controller (e.g., 210 of FIG. 2) will issue the REFab command to the memory device (e.g., 100 of FIG. 1, 220 of FIG. 2, and/or 300 of FIG. 3). In some embodiments, the memory device will write a request for the REFab command to the mode register.

In some embodiments, the memory device (e.g., 100 of FIG. 1, 220 of FIG. 2, and/or 300 of FIG. 3) may compare the refresh deficit count values (e.g., 232/233 of FIG. 2 and/or 316 of FIG. 3) of all of the banks to each other and determine how many REFab commands to provide. For example, the memory may compare the refresh deficit count values and determine a maximum one of the refresh deficit count values. The memory device may pass the maximum refresh deficit count value to the controller (e.g., 210 of FIG. 2) so that the controller may issue REFab commands accordingly. The controller may determine how many REFab commands to provide based on the maximum value. For example, the controller may issue enough REFab commands to clear the maximum refresh deficit count value.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. A method comprising:
changing a first count value based on how many refresh intervals have elapsed;
changing a second count value based on how many refresh operations have been performed on at least a portion of a bank;
determining a refresh deficit count based on a difference between the second count value and the first count value; and
writing the refresh deficit count to a mode register.

2. The method of claim 1, further comprising setting the refresh deficit count equal to the difference of the second count value and the first count value if the second count value is less than the first count value and setting the refresh deficit count equal to zero if the minimum count value is greater than or equal to the first count value.

3. The method of claim 1, further comprising:
changing the second count value based on how many refresh operations have been performed on a first portion of the bank;
changing a third count value based on how many refresh operations have been performed on a second portion of the bank; and
determining the refresh deficit count based on the first count value and the second count value or the third count value.

4. The method of claim 3, further comprising:
comparing the second count value and the third count value to find a minimum count value; and
determining the refresh deficit count based on a difference between the first count value and the minimum of the second and the third count values.

5. The method of claim 3, further comprising halving the first count value before determining the refresh deficit count.

6. The method of claim 1, wherein writing the refresh deficit count to the mode register occurs after a scheduled number of refresh intervals.

7. The method of claim 6, wherein the scheduled number of refresh intervals is 4 and wherein writing the refresh deficit count starts in a second refresh interval of the refresh period.

8. A method comprising:
updating a refresh deficit value in a mode register;
waiting a first scheduled number of refresh interval periods before updating the refresh deficit value again;
reading the refresh deficit value from the mode register; and
waiting a second scheduled number of the refresh interval periods before reading the refresh deficit value again,
wherein the updating and the reading do not happen at a same time.

9. The method of claim 8, wherein the first scheduled number and the second scheduled number are the same, the method further comprising:
starting the updating on a first value of a count of refresh interval periods; and
starting the reading on a second value of the count of refresh interval periods which is different than the first value.

10. The method of claim 8, further comprising:
performing the updating every first scheduled number of refresh interval periods with a refresh control circuit of a memory; and
performing the reading every second scheduled number of refresh interval periods with a controller of the memory.

11. The method of claim 10, further comprising:
counting the refresh interval periods with a first refresh interval counter circuit of the memory;
counting the refresh interval periods with a second refresh interval counter circuit of the controller.

12. The method of claim 11, further comprising: setting the first refresh interval counter circuit and the second refresh interval counter circuit to a same value at an initial time.

13. The method of claim 8, wherein the refresh interval is based on a refresh mode.

14. A system comprising:
a memory device comprising:
a bank;
a mode register configured to store a refresh deficit count associated with the bank;
a refresh period counter circuit configured to count the number of elapsed refresh intervals; and
a refresh control circuit associated with the bank, the refresh control circuit comprising:
a first refresh address counter configured to count a number of refresh operations performed on at least a portion of the bank; and
a refresh deficit counter configured to generate a refresh deficit count based, at least in part, on a difference between the number of performed refresh operations and the number of elapsed refresh intervals, wherein the refresh control circuit is further configured to write the refresh deficit count to the mode register deficit counter; and
a controller configured to issue mode register read (MRR) commands to the refresh deficit count in the mode register.

15. The system of claim 14, wherein the first refresh address counter is configured to count a number of refresh operations performed on a first portion of the bank, and wherein the refresh control circuit is further comprising:
a second refresh address counter configured to count a number of refresh operations performed on a second portion of the bank; and
a comparator configured to determine a minimum count value comprising the lesser of the number of refresh operations performed on the first portion of the bank or the number of refresh operations performed on the second portion of the bank; and
wherein the refresh deficit counter is further configured to store a difference between the minimum count value and the number of elapsed refresh intervals.

16. The system of claim 15, wherein the refresh deficit counter is further configured to store a zero if the minimum count value is greater than or equal to the number of elapsed refresh intervals.

17. The system of claim 14, wherein the refresh deficit counter is further configured to store a zero if the number of refresh operations performed on the first portion of the bank is greater than or equal to the number of elapsed refresh intervals.

18. The system of claim 14, wherein the controller is configured to perform the MRR operations at a different time than when the refresh deficit counter writes the refresh deficit count to the mode register.

19. The system of claim 18, wherein the controller comprises a second refresh period counter circuit configured to count the number of the elapsed refresh intervals,
wherein the controller is configured to determine when to perform the MRR operations based on the count of the number of elapsed refresh intervals by the second refresh period counter circuit.

20. The system of claim 19, wherein the refresh deficit counter circuit is configured to determine when to write the refresh deficit count to the mode register based on the count of the number of elapsed refresh intervals by the refresh period counter circuit.
